(19) United States
(12) Patent Application Publication
(10) Pub. No.: US 2021/0130617 A1
(43) Pub. Date: May 6, 2021

(54) COLORING COMPOSITION, FILM, COLOR FILTER, METHOD FOR MANUFACTURING COLOR FILTER, SOLID-STATE IMAGING ELEMENT, AND IMAGE DISPLAY DEVICE

(71) Applicant: FUJIFILM Corporation, Tokyo (JP)

(72) Inventors: Yasuhiro Sawamura, Haibara-gun (JP); Masaomi Makino, Haibara-gun (JP); Akio Mizuno, Haibara-gun (JP); Yushi Kaneko, Haibara-gun (JP); Hiroaki Idei, Haibara-gun (JP)

(73) Assignee: FUJIFILM Corporation, Tokyo (JP)

(21) Appl. No.: 17/142,730

(22) Filed: Jan. 6, 2021

Related U.S. Application Data
(63) Continuation of application No. PCT/JP2019/026773, filed on Jul. 5, 2019.

(30) Foreign Application Priority Data
Jul. 13, 2018 (JP) 2018-133334

(51) Int. Cl. C09B 57/00; G03F 7/00; C09B 67/46

(52) U.S. Cl. CPC C09B 57/007; G02F 1/133516; C09B 67/009; G03F 7/0007

(57) ABSTRACT

Provided are a coloring composition including a green colorant, a resin, and an organic solvent, in which the green colorant includes a squarylium compound having a solubility of 30 mg/L or less in propylene glycol methyl ether acetate at 25° C.; a film formed of the coloring composition; a color filter; a method for manufacturing a color filter; a solid-state imaging element; and an image display device.

### CROSS-REFERENCE TO RELATED APPLICATIONS

This application is a Continuation of PCT International Application No. PCT/JP2019/026773 filed on Jul. 5, 2019, which claims priority under 35 U.S.C § 119(a) to Japanese Patent Application No. 2018-133334 filed on Jul. 13, 2018. Each of the above application(s) is hereby expressly incorporated by reference, in its entirety, into the present application.

### BACKGROUND OF THE INVENTION

### 1. Field of the Invention

The present invention relates to a coloring composition including a green colorant. The present invention further relates to a film formed of the coloring composition, a color filter, a method for manufacturing a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. As a key device of a display or an optical element, a color filter has been used. The color filter normally includes pixels of three primary colors of red, green, and blue, and acts to separate transmitted light into the three primary colors.

Each color pixel of the color filter is manufactured using a coloring composition including a colorant. For example, JP2015-163956A discloses an invention relating to a green coloring composition for a color filter, which includes a green colorant, a near-infrared absorber, and a polymerizable compound. Examples of the green colorant include Color Index Pigment Green 7, 10, 36, 37, and 58. All of these are phthalocyanine pigments.

In addition, JP2015-172178A discloses an invention relating to a coloring composition formed of a dye which has a group including a silicon atom and has a squarylium skeleton. In paragraph “0006” of JP2015-172178A, it is disclosed that the dye having a squarylium skeleton has a high solubility in an organic solvent.

In addition, JP2012-168258A discloses an invention relating to a coloring composition which includes a cyanine dye or squarylium dye (A) exhibiting an absorption maximum of 720 nm or more in methanol, an alkali-soluble polymer (B) having a carboxylic acid, sulfonic acid, or phosphoric acid value of 150 mgKOH/g or less, and a polymerizable compound (C), in which the dye (A) has an absorption maximum of at least 620 to 670 nm in the alkali-soluble polymer (B).

### SUMMARY OF THE INVENTION

Further improvement in light resistance is desired for a film formed using a coloring composition. In addition, the coloring composition may be used immediately after manufacture, or may be used after being stored for a long time after manufacture. Therefore, further improvement in storage stability of the coloring composition is desired.

Accordingly, an object of the present invention is to provide a coloring composition with which a film having good storage stability and excellent light resistance can be formed. Another object of the present invention is to provide a film formed of the coloring composition, a color filter, a method for manufacturing a color filter, a solid-state imaging element, and an image display device.

According to the studies conducted by the present inventor, it has been found that the above-described object can be achieved by adopting the following configuration, thereby leading to the completion of the present invention. Therefore, the present invention provides the following.

<1> A coloring composition comprising:

a green colorant;

a resin; and

an organic solvent,

in which the green colorant includes a squarylium compound having a solubility of 30 mg/L or less in propylene glycol methyl ether acetate at 25° C.

<2> The coloring composition according to <1>,

in which the squarylium compound is a compound having a maximum absorption wavelength in a wavelength range of 600 to 700 nm.

<3> The coloring composition according to <1> or <2>,

in which the squarylium compound is a compound represented by Formula (1),

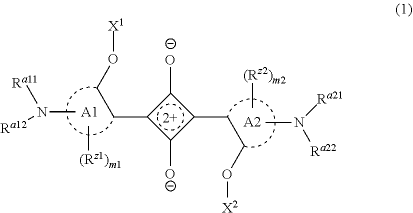

in Formula (1), A1 and A2 each independently represent an aromatic ring structure which may have a fused ring,

R^{z1} and R^{z2} each independently represent a substituent,

at least one of R^{z1}'s and at least one of R^{z2}'s may be bonded to each other to form a ring structure,

m1 represents an integer of 0 to mA1, in which mA1 represents a maximum number of substituents in A1,

m2 represents an integer of 0 to mA2, in which mA2 represents a maximum number of substituents in A2,

R^{z1} may forma ring structure with any one of R^{a11} or R^{a12},

R^{z2} may form a ring structure with any one of R^{a21} or R^{a22},

X¹ and X² each independently represent a hydrogen atom or a substituent, in which X and X² may be bonded to each other to form a ring structure,

R^{a11}, R^{a12}, R^{a21}, and R^{a22} each independently represent an aromatic ring structure which may have a fused ring, and

at least one of R^{a11}, R^{a12}, R^{a21}, or R^{a22} represents an aromatic ring structure having a substituent at an adjacent position to an atom to which a nitrogen atom provided by A1 or A2 in Formula (1) is bonded, or an aromatic ring structure having a fused ring at the adjacent position to the atom to which the nitrogen atom of Formula (1) is bonded.

<4> The coloring composition according to <3>,

in which an average value of solubility parameters of R^{a11}, R^{a12}, R^{a21}, and R^{a22} in Formula (1) is 8.9 (cal/cm³)^{1/2} or more.

<5> The coloring composition according to any one of <1> to <4>, further comprising:

a yellow pigment.

<6> The coloring composition according to any one of <1> to <5> further comprising:

a pigment derivative.

<7> The coloring composition according to any one of <1> to <6>, further comprising:

a polymerizable compound.

<8> The coloring composition according to any one of <1> to <7>, further comprising:

a photopolymerization initiator.

<9> The coloring composition according to any one of <1> to <8>,

in which the resin includes an alkali-soluble resin.

<10> The coloring composition according to any one of <1> to <9>,

in which the coloring composition is used for forming a pixel of a color filter.

<11> The coloring composition according to <10>,

in which the coloring composition is used for forming a green pixel.

<12> A film which is formed of the coloring composition according to any one of <1> to <11>.

<13> A color filter comprising:

the film according to <12>.

<14> A method for manufacturing a color filter, comprising:

a step of forming a coloring composition layer on a support using the coloring composition according to any one of <1> to <11>; and

a step of forming a pattern on the coloring composition layer by a photolithography method or a dry etching method.

<15> A solid-state imaging element comprising:

the film according to <12>.

<16> An image display device comprising:

the film according to <12>.

According to the present invention, it is to provide a coloring composition with which a film having good storage stability and excellent light resistance can be formed. It is also possible to provide a film formed of the coloring composition, a color filter, a method for manufacturing a color filter, a solid-state imaging element, and an image display device.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene measured by gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” denotes not only an individual step but also a step which is not clearly distinguishable from another step as long as an effect expected from the step can be achieved.

<Coloring Composition>

The coloring composition according to an embodiment of the present invention is a coloring composition including a green colorant, a resin, and an organic solvent, in which the green colorant includes a squarylium compound having a solubility of 30 mg/L or less in propylene glycol methyl ether acetate at 25° C.

Since the squarylium compound included in the coloring composition according to the embodiment of the present invention has 30 mg/L or less of the above-described solubility, dispersibility in the coloring composition is good and aggregation or the like of the squarylium compound is unlikely to occur in the composition. Therefore, the coloring composition according to the embodiment of the present invention has excellent storage stability. Although a presumption, the reason why dispersibility in the coloring composition can be improved due to that the solubility of the squarylium compound is 30 mg/L or less is considered that the squarylium compound in the coloring composition can be moderately mixed with the resin or the organic solvent, and thus the aggregation or the like of the squarylium compound can be suppressed. On the other hand, in a case where the above-described solubility is too high, since the balance of the interaction between the squarylium compound, the resin, and the organic solvent is disturbed, it is considered that dispersibility is poor.

In addition, by using the above-described coloring composition, discoloration or the like caused by light irradiation can be suppressed and it is possible to form a film having excellent light resistance.

Furthermore, since the above-described squarylium compound used in the coloring composition according to the embodiment of the present invention as a green colorant has 30 mg/L or less of the above-described solubility, it is presumed that stabilization will occur due to association of squarylium molecules, and heat resistance of the obtained film can also be improved.

In addition, since the above-described squarylium compound used in the coloring composition according to the embodiment of the present invention as a green colorant has 30 mg/L or less of the above-described solubility, it is presumed that the aggregation is unlikely to occur even in a film, and as a result, it is also possible to form a film (preferably a green-colored film) which has sharp absorption of light having a wavelength near green, has a smaller overlap of absorption with red, and has excellent color separation characteristics from other colors.

The coloring composition according to the embodiment of the present invention can be preferably used as a coloring composition for forming a pixel of a color filter, and can be more preferably used as a coloring composition for forming a green pixel of a color filter. In addition, the coloring composition according to the embodiment of the present invention can also be used as a composition for forming a color microlens. Examples of a method for manufacturing the color microlens include the method described in JP2018-010162A.

Hereinafter, the respective components used in the coloring composition according to the embodiment of the present invention will be described.

<<Green Colorant>>

The coloring composition according to the embodiment of the present invention contains a green colorant. In the coloring composition according to the embodiment of the present invention, as the green colorant, a compound including a squarylium compound (hereinafter, also referred to as a squarylium compound A) having a solubility of 30 mg/L or less in propylene glycol methyl ether acetate at 25° C. is used.

The solubility of the squarylium compound A in propylene glycol methyl ether acetate at 25° C. is preferably 25 mg/L or less, more preferably 20 mg/L or less, and still more preferably 10 mg/L or less. The lower limit of the solubility is not particularly limited, but may be, for example, 0.1 mg/L or more. The value of the solubility of the squarylium compound A is a value measured according to the method in Examples described later.

The squarylium compound A is preferably a compound having a maximum absorption wavelength in a wavelength range of 600 to 700 nm, more preferably a compound having a maximum absorption wavelength in a wavelength range of 620 to 695 nm, and still more preferably a compound having a maximum absorption wavelength in a wavelength range of 640 to 690 nm. The value of the maximum absorption wavelength of the squarylium compound A is a value measured according to the method in Examples described later.

The molar absorption coefficient of the squarylium compound A at the maximum absorption wavelength is preferably 2.0×10⁵ L/(mol·cm) or more and more preferably 2.1×10⁵ L/(mol·cm) or more. The molar absorption coefficient is a value measured using Cary 5000 UV-Vis-NIR spectrophotometer (manufactured by Agilent Technologies, Inc.).

The squarylium compound A is preferably a compound represented by Formula (1).

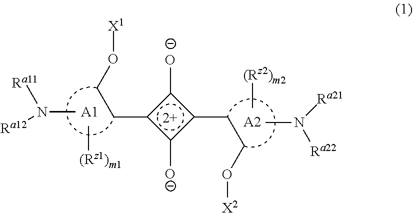

In Formula (1), A1 and A2 each independently represent an aromatic ring structure which may have a fused ring,

R^{z1} and R^{z2} each independently represent a substituent,

at least one of R's and at least one of R^{z2}'s may be bonded to each other to form a ring structure,

m1 represents an integer of 0 to mA1, in which mA1 represents a maximum number of substituents in A1,

m2 represents an integer of 0 to mA2, in which mA2 represents a maximum number of substituents in A2,

R^{z1} may form a ring structure with any one of R^{a11} or R^{a12},

R^{z2} may form a ring structure with any one of R^{a21} or R^{a22},

X¹ and X² each independently represent a hydrogen atom or a substituent, in which X¹ and X² may be bonded to each other to form a ring structure,

R^{a11}, R^{a12}, R^{a21}, and R^{a22} each independently represent an aromatic ring structure which may have a fused ring, and

at least one of R^{a11}, R^{a12}, R^{a21}, or R^{a22} represents an aromatic ring structure having a substituent at an adjacent position to an atom to which a nitrogen atom provided by A1 or A2 in Formula (1) is bonded, or an aromatic ring structure having a fused ring at the adjacent position to the atom to which the nitrogen atom of Formula (1) is bonded.

In the compound represented by Formula (1), cations are present without being localized as shown in the following formulae. That is, the compound represented by Formula (1) is equivalent to a compound represented by Formula (1-1) or a compound represented by Formula (1-2).

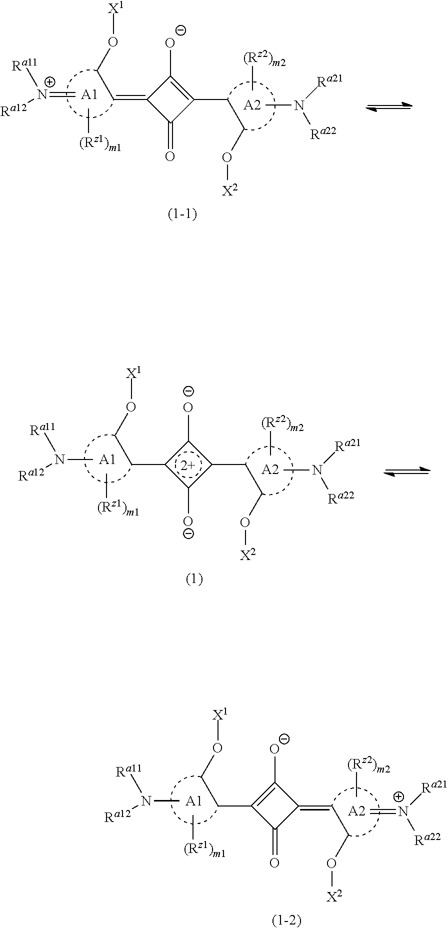

In Formula (1), Aland A2 each independently represent an aromatic ring structure which may have a fused ring. A1 and A2 are each independently preferably an aromatic ring structure having 4 to 10 carbon atoms, more preferably an aromatic hydrocarbon ring structure having 6 to 10 carbon atoms, and still more preferably a benzene ring structure. In addition, it is preferable that at least one of A1 or A2 is a benzene ring structure, and it is more preferable that both A1 and A2 are a benzene ring structure. In a case where A1 and A2 are an aromatic heterocyclic structure, an aromatic heterocyclic structure including a sulfur atom, a nitrogen atom, or an oxygen atom as a ring member and having 4 or 5 carbon atoms is preferable, and a thiophene ring structure or a pyrrole ring structure is more preferable. A nitrogen atom of the pyrrole ring structure may be substituted with an alkyl group having 1 to 12 carbon atoms.

In Formula (1), R^{z1} and R^{z2} each independently represent a substituent, and an alkyl group, a hydroxy group, an alkoxy group, an aryl group, or a halogen atom is preferable and an alkyl group, a hydroxy group, or an alkoxy group is more preferable. The number of carbon atoms in the alkyl group is preferably 1 to 12. The number of carbon atoms in the alkoxy group is preferably 1 to 12. The number of carbon atoms in the aryl group is preferably 4 to 10.

In Formula (1), at least one of R's and at least one of R^{z2}'s may be bonded to each other to form a ring structure, and examples of the ring structure formed include an aliphatic hydrocarbon ring structure and a heterocyclic structure.

In Formula (1), m1 represents an integer of 0 to mA1, and from the viewpoint that A1 is preferably a benzene ring structure, m1 is preferably an integer of 0 to 4, more preferably an integer of 0 to 2, and still more preferably 0 or 1.

In Formula (1), m2 represents an integer of 0 to mA2, and from the viewpoint that A2 is preferably a benzene ring structure, m2 is preferably an integer of 0 to 4, more preferably an integer of 0 to 2, and still more preferably 0 or 1.

In Formula (1), R^{z1} may form a ring structure with any one of R^{a11} or R^{a12}, and R^{z2} may form a ring structure with any one of R^{a21} or R^{a22}. Examples of the ring structure formed as described above include a 5-membered or 6-membered ring structure including the nitrogen atom of Formula (1) as a ring member, and preferred examples thereof include a pyrrolidine ring structure including the nitrogen atom of Formula (1) as a ring member.

In Formula (1), X¹ and X² each independently represent a hydrogen atom or a substituent, and a hydrogen atom or an alkyl group is preferable and a hydrogen atom is more preferable. In addition, X¹ and X² may be each independently bonded to an oxygen atom of Formula (1) to form an alkyl ester structure, an alkyl ether structure, or a carbamate structure, and the above-described alkyl ester structure, alkyl ether structure, or carbamate structure may be bonded to each other to form a ring.

R^{a11}, R^{a12}, R^{a21}, and R^{a22} each independently represent an aromatic ring structure which may have a fused ring, and at least one of R^{a11}, R^{a12}, R^{a21}, or R^{a22} represents an aromatic ring structure having a substituent at an adjacent position to an atom to which a nitrogen atom provided by A1 or A2 in Formula (1) is bonded, or an aromatic ring structure having a fused ring at the adjacent position to the atom to which the nitrogen atom of Formula (1) is bonded. R^{a11} and R^{a12} may be bonded to each other to form a ring structure, but preferably do not form a ring structure. In addition, R^{a21} and R^{a22} may be bonded to each other to form a ring structure, but preferably do not form a ring structure.

It is sufficient that the aromatic ring structure having a substituent at an adjacent position to an atom to which the nitrogen atom of Formula (1) is bonded has a substituent at at least one of adjacent positions to the atom to which the nitrogen atom on the aromatic ring structure of Formula (1) is bonded, and the aromatic ring structure having a substituent at an adjacent position to an atom to which the nitrogen atom of Formula (1) is bonded may have substituents at both of the above-described adjacent positions or may have a substituent at one of the above-described adjacent positions and have a fused ring at the other of the above-described adjacent positions.

In addition, it is sufficient that the aromatic ring structure having a fused ring at the above-described adjacent position to the nitrogen atom of Formula (1) has a fused ring at at least one of the above-described adjacent positions to the nitrogen atom on the aromatic ring structure of Formula (1), and the aromatic ring structure having a fused ring at the above-described adjacent position to the nitrogen atom of Formula (1) may have fused rings at both of the above-described adjacent positions.

—Aromatic Ring Structure Having Substituent at Adjacent Position—

In the present specification, in a case where R^{a11}, R^{a12}, R^{a21}, or R^{a22} is the aromatic ring structure having a substituent at an adjacent position to an atom to which the nitrogen atom of Formula (1) is bonded, the case refers to that, for example, R^{a11}, R^{a12}, R^{a21}, or R^{a22} is a structure represented by Formula (A).

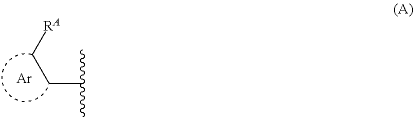

In Formula (A), Ar represents an aromatic ring structure, R^{A} represents a substituent at an adjacent position to the atom in Ar to which the nitrogen atom of Formula (1) is bonded, and a wave line portion represents a binding site with the nitrogen atom of Formula (1). In Formula (A), Ar may have a substituent other than R^{A}, or may have a fused ring.

As the aromatic ring structure having a substituent at the above-described adjacent position (for example, Ar in Formula (A)), an aromatic ring structure having 4 to 20 carbon atoms is preferable, an aromatic hydrocarbon ring structure having 6 to 20 carbon atoms is more preferable, and a benzene ring structure is still more preferable. In a case where the aromatic ring structure having a substituent at the above-described adjacent position is an aromatic heterocyclic structure, an aromatic heterocyclic structure including a sulfur atom, a nitrogen atom, or an oxygen atom as a ring member and having 4 to 10 carbon atoms is preferable, and a thiophene ring structure, a furan ring structure, or a pyrrole ring structure is more preferable. In addition, it is sufficient that the aromatic ring structure having a substituent at the above-described adjacent position has a substituent at at least one of the two adjacent positions, and the aromatic ring structure having a substituent at the above-described adjacent position may have substituents at both of the adjacent positions. In addition, the aromatic ring structure having a substituent at the above-described adjacent position may further have a substituent at a position other than the adjacent position. It is sufficient that the substituent at the adjacent position (for example, R^{A} in Formula (A)) is a substituent larger than a hydrogen atom, and an alkyl group, a halogenated alkyl group (preferably a fluoroalkyl group), an aryl group, an alkoxy group, a thioalkyl group, a thioaryl group, an amino group, a sulfide group, an acyl group, a nitro group, a cyano group, an amide group, or a halogen atom is preferable, a nitro group, a cyano group, an amide group, an acyl group, an aryl group, or a halogen atom is more preferable, and a nitro group, a cyano group, an amide group, or an acyl group is still more preferable. The number of carbon atoms in the alkyl group, halogenated alkyl group, and alkoxy group is preferably 1 to 5. The number of carbon atoms in the aryl group is preferably 4 to 10. The number of carbon atoms in the acyl group is preferably 2 to 6. As the halogen atom, a fluorine atom or a chlorine atom is preferable. Preferred examples of the substituent at a position other than the adjacent position include above substituents, and the preferred aspect is also the same.

—Aromatic Ring Structure having Fused Ring at Adjacent Position—

In the present specification, in a case where R^{a11}, R^{a12}, R^{a21}, or R^{a22} is the aromatic ring structure having a fused ring at an adjacent position to an atom to which the nitrogen atom of Formula (1) is bonded, the case refers to that, for example, R^{a11}, R^{a12}, R^{a21}, or R^{a22} is a structure represented by Formula (B).

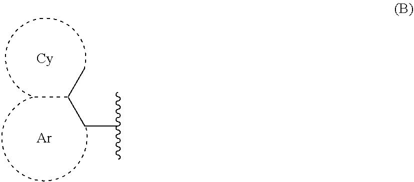

In Formula (B), Ar represents an aromatic ring structure, Cy represents a fused ring at an adjacent position to the atom in Ar to which the nitrogen atom of Formula (1) is bonded, and a wave line portion represents a binding site with the nitrogen atom of Formula (1). In Formula (B), Ar and Cy may have a substituent, or may further have a fused ring.

As the aromatic ring structure having a fused ring at the above-described adjacent position (for example, Ar in Formula (B)), an aromatic ring structure having 6 to 20 carbon atoms is preferable and a benzene ring structure is more preferable.

In a case where the aromatic ring structure having a fused ring at the above-described adjacent position is an aromatic heterocyclic structure, an aromatic heterocyclic structure including a sulfur atom, a nitrogen atom, or an oxygen atom as a ring member and having 4 to 8 carbon atoms is preferable, and a thiophene ring structure, a furan ring structure, or a pyrrole ring structure is more preferable.

In the present specification, having a fused ring at the above-described adjacent position means that a fused ring including at least a carbon atom on the aromatic ring structure, which is at the adjacent position to the atom to which the above-described nitrogen atom is bonded, is formed.

As the fused ring in the aromatic ring structure having a fused ring at an adjacent position in R^{a11}, R^{a12}, R^{a21}, and R^{a22} to the atom to which the nitrogen atom is bonded (for example, Cy in Formula (B)), an aromatic hydrocarbon ring is preferable, an aromatic hydrocarbon ring having 6 to 20 carbon atoms is more preferable, and a benzene ring is still more preferable.

At least one of R^{a11}, R^{a12}, R^{a21}, or R^{a22} is preferably a structure represented by Formula (R-1). According to this aspect, rotational movement of these structures is suppressed so that the absorption is sharpened, and more excellent spectral characteristics are easily obtained.

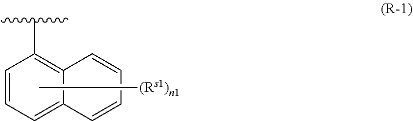

In Formula (R-1), R^{s1} represents a substituent, and in a case where n1 is 2 or more, a plurality of R^{s1}'s are bonded to each other to form a ring structure. n1 represents an integer of 0 to 7, and a wave line portion represents a binding site with the nitrogen atom of Formula (1).

As the substituent represented by R^{s1}, an alkyl group, a halogenated alkyl group (preferably a fluoroalkyl group), an aryl group, an alkoxy group, a thioalkyl group, a thioaryl group, an amino group, a sulfide group, an acyl group, a nitro group, a cyano group, an amide group, or a halogen atom is preferable, a nitro group, a cyano group, an amide group, an acyl group, an aryl group, or a halogen atom is more preferable, and a nitro group, a cyano group, an amide group, or an acyl group is still more preferable. The number of carbon atoms in the alkyl group, halogenated alkyl group, and alkoxy group is preferably 1 to 5. The number of carbon atoms in the aryl group is preferably 4 to 10. The number of carbon atoms in the acyl group is preferably 2 to 6. As the halogen atom, a fluorine atom or a chlorine atom is preferable.

n1 represents an integer of 0 to 7, and is preferably an integer of 0 to 2 and more preferably 0 or 1.

In Formula (1), it is sufficient that at least one of R^{a11}, R^{a12}, R^{a21}, or R^{a22} is the above-described aromatic ring structure, and any one of R^{a11}, R^{a12}, R^{a21}, or R^{a22} may be an aromatic ring structure having neither a substituent nor a fused ring at the above-described adjacent position.

Examples of the aromatic ring structure having neither a substituent nor a fused ring at the above-described adjacent position include an unsubstituted aromatic ring structure, an aromatic ring structure having no substituent at the above-described adjacent position and having a substituent at a position other than the above-described adjacent position, and an aromatic ring structure having no fused ring at the above-described adjacent position and having a fused ring at a position other than the above-described adjacent position. As the aromatic ring structure having neither a substituent nor a fused ring at the above-described adjacent position, an aromatic ring structure having 4 to 20 carbon atoms is preferable, an aromatic hydrocarbon ring structure having 6 to 20 carbon atoms is more preferable, and a benzene ring structure is still more preferable.

In a case where the aromatic ring structure having neither a substituent nor a fused ring at the above-described adjacent position is an aromatic heterocyclic structure, an aromatic heterocyclic structure including a sulfur atom, a nitrogen atom, or an oxygen atom as a ring member and having 4 to 8 carbon atoms is preferable, and a thiophene ring structure, a furan ring structure, or a pyrrole ring structure is preferable.

Examples of the substituent in the aromatic ring structure having a substituent at a position other than the above-described adjacent position include the above-described substituents.

As the fused ring in the aromatic ring structure having a fused ring at a position other than the above-described adjacent position, an aromatic ring structure having 4 to 20 carbon atoms is preferable, an aromatic hydrocarbon ring structure having 6 to 20 carbon atoms is more preferable, and a benzene ring structure is still more preferable.

In the entire of Formula (1), the total number of the substituent at an adjacent position to the atom to which the nitrogen atom of Formula (1) is bonded, and fused ring at an adjacent position to the atom to which the nitrogen atom of Formula (1) is bonded, the substituent and fused ring being included in R^{a11}, R^{a12}, R^{a21}, and R^{a22}, is preferably 1 or more and more preferably 2 or more. The upper limit is preferably 8 or less and more preferably 4 or less.

In the entire of Formula (1), the preferred number of R-plane carbon atoms forming aromatic rings is preferably 36 atoms (6 benzene rings) or more, more preferably 40 atoms (5 benzene rings and 1 naphthyl ring) or more, and still more preferably 44 atoms (4 benzene rings and 2 naphthyl rings) or more.

In addition, the average value of solubility parameters of R^{a11}, R^{a12}, R^{a21}, and R^{a22} in Formula (1) is preferably 8.9 (cal/cm³)/2 or more, more preferably 9.5 (cal/cm³)/2 or more, and still more preferably 10 (cal/cm³)^{1/2} or more. The upper limit is not particularly limited, but can be set to 14.5 (cal/cm³)^{1/2} or less. According to this aspect, solubility of the squarylium compound A in propylene glycol methyl ether acetate can be more reduced, and the effects intended by the present invention can be more significantly and easily obtained. In addition, SP value of each of R^{a11}, R^{a12}, R^{a21}, and R^{a22} is preferably 8.0 (cal/cm³)^{1/2} or more, more preferably 8.5 (cal/cm³)^{1/2} or more, still more preferably 9.0 (cal/cm³)^{1/2} or more, and particularly preferably 9.5 (cal/cm³)^{1/2} or more.

In the present specification, the solubility parameter (SP value) is a value calculated in accordance with the Okitsu method (“Journal of the Adhesion Society of Japan”, 29(5) (1993), authored by Toshinao Okitsu). Specifically, the SP value is calculated using the following expression. ΔF denotes the value described in the journal.

SP value (δ)=ΣΔF (molar attraction constants)/V (molar volume)

In addition, the SP values of R^{a11}, R^{a12}, R^{a21}, and R^{a22} are values calculated by replacing the bonding hand (position at which the nitrogen atom of Formula (1) is bonded) with a hydrogen atom.

Specific examples of the squarylium compound A include compounds having the following structures. In the following structural formulae, Ph represents a phenyl group.

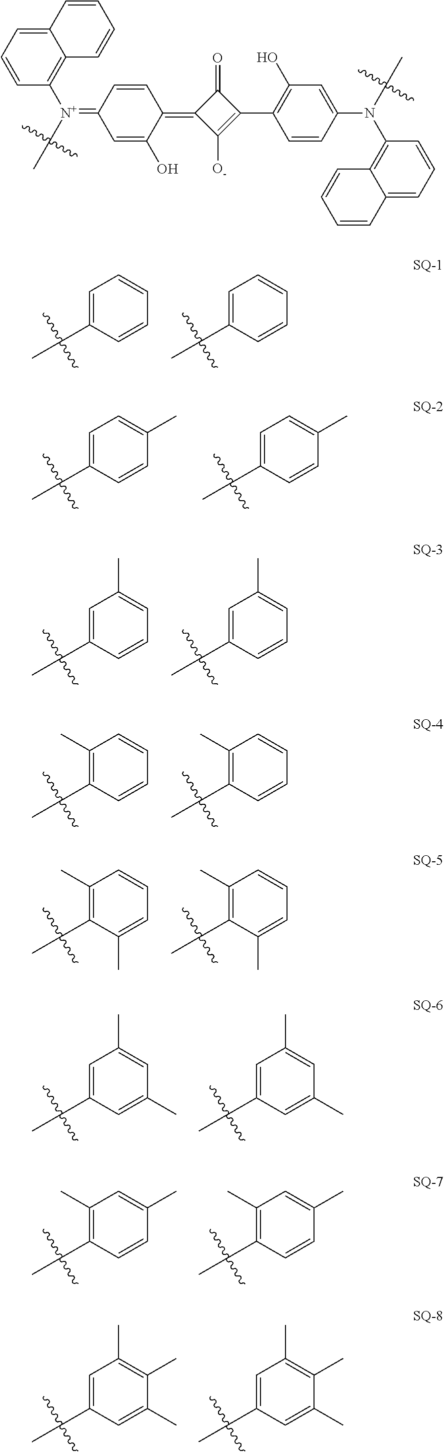

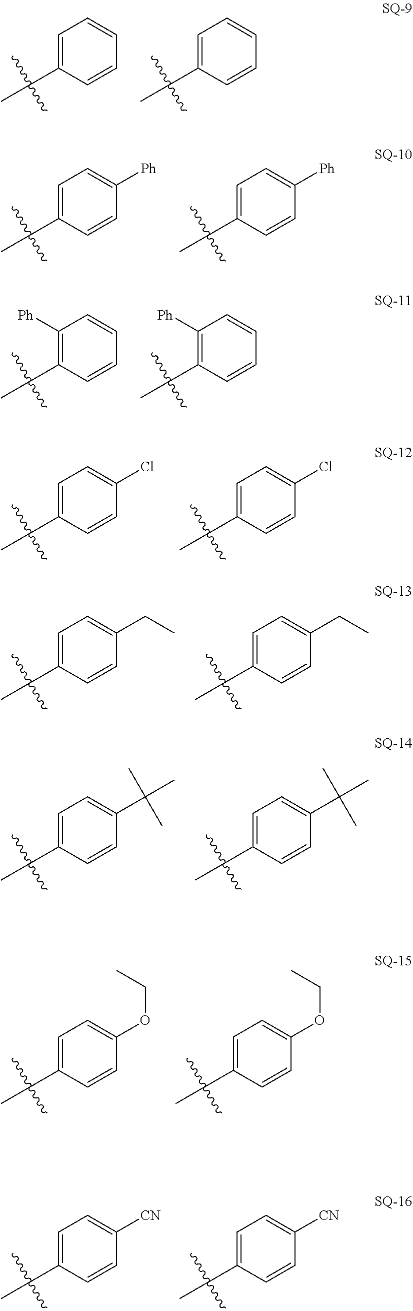

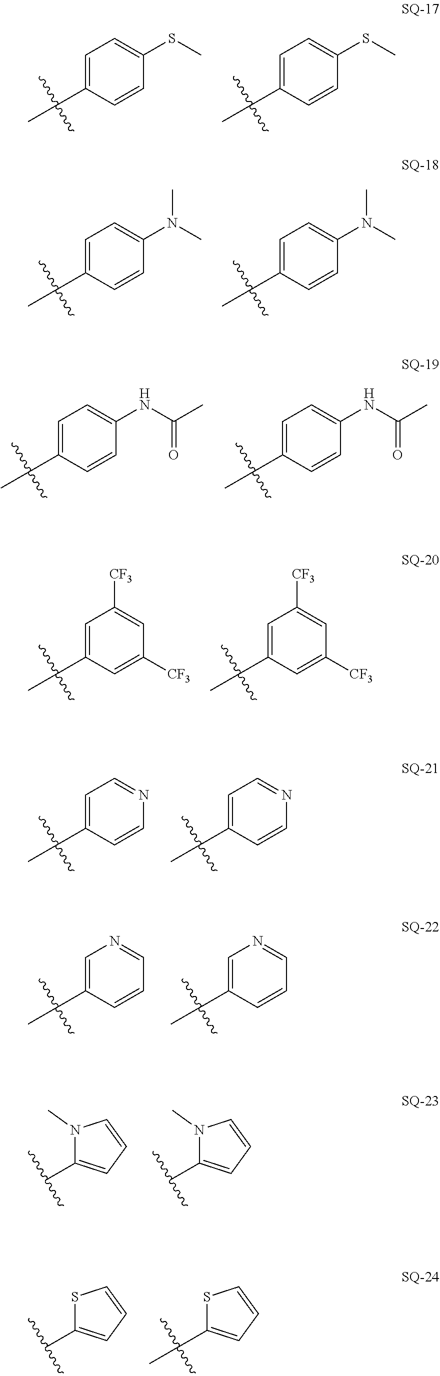

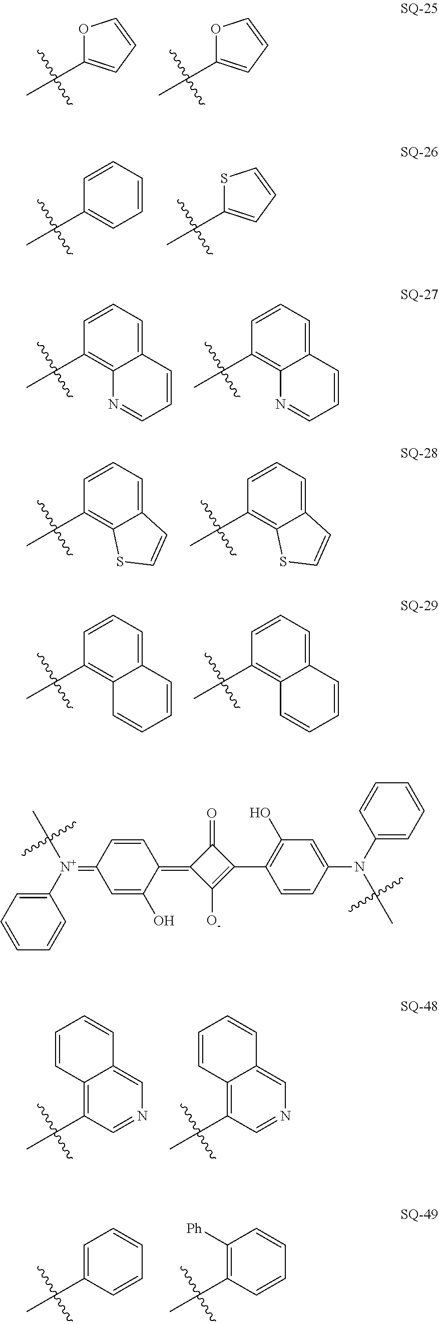

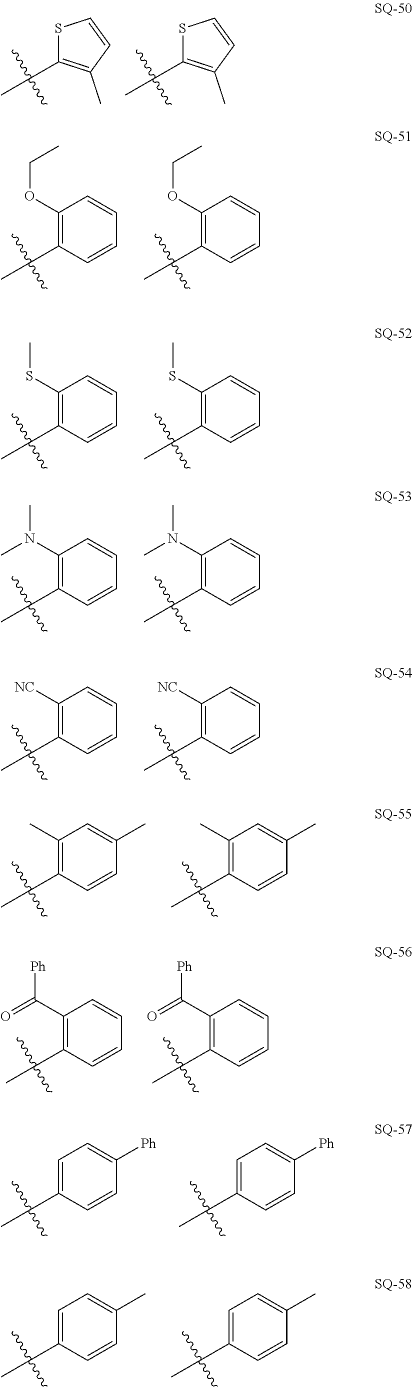

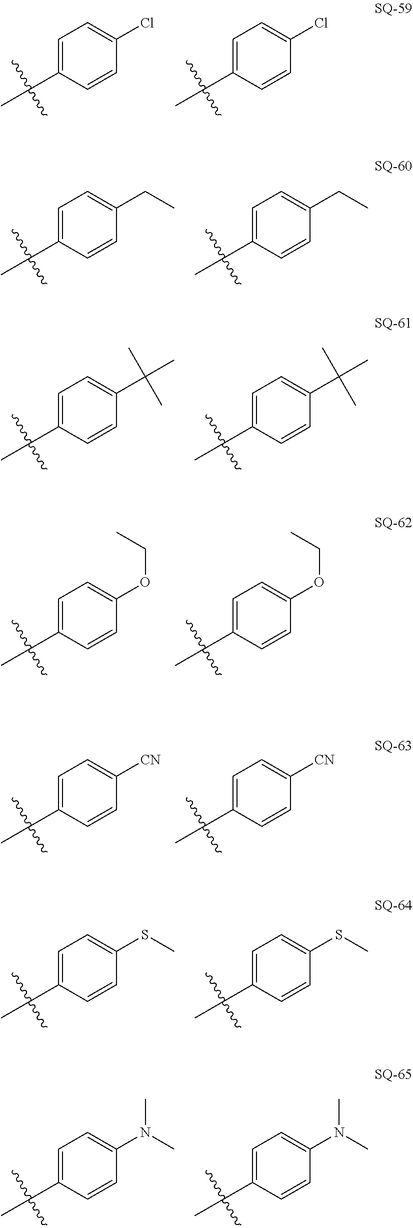

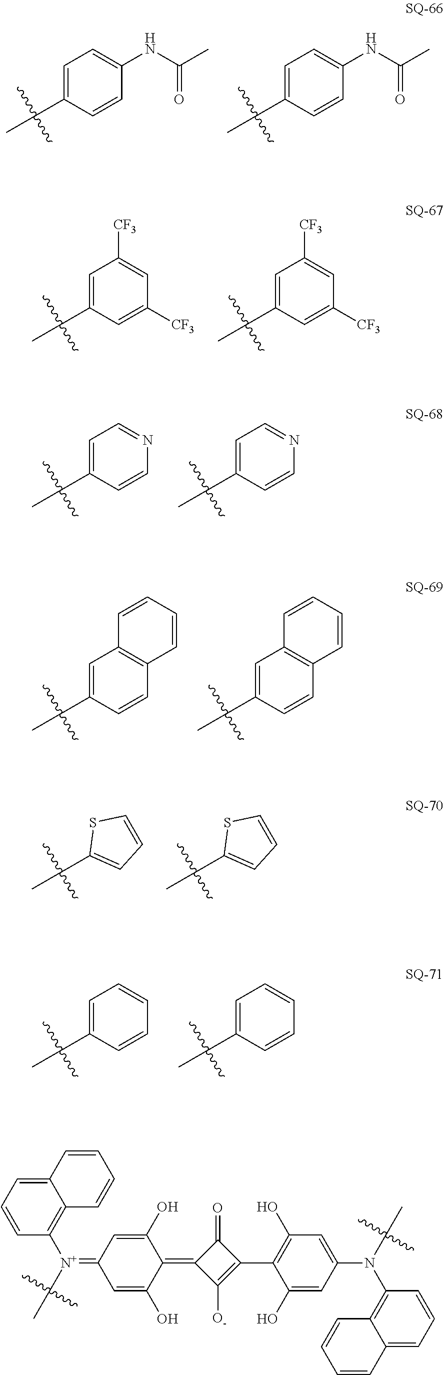

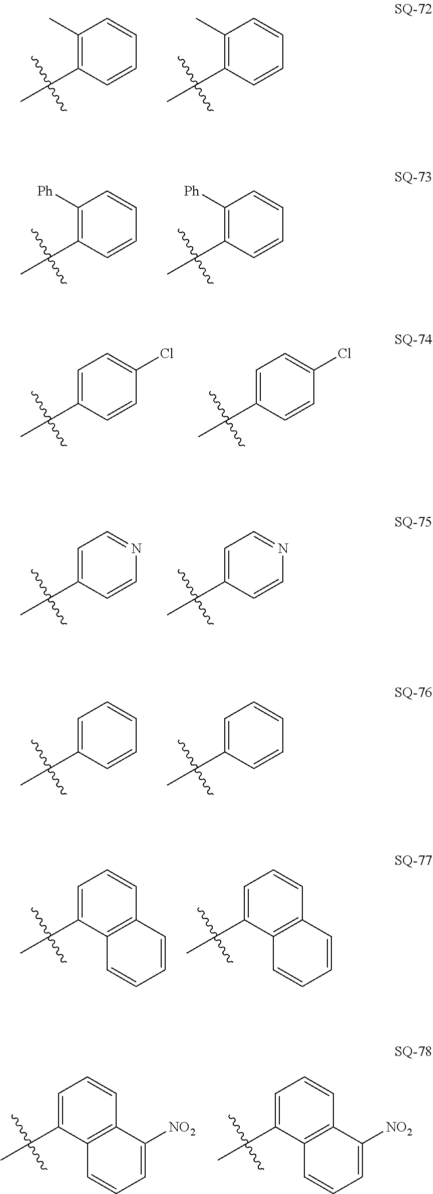

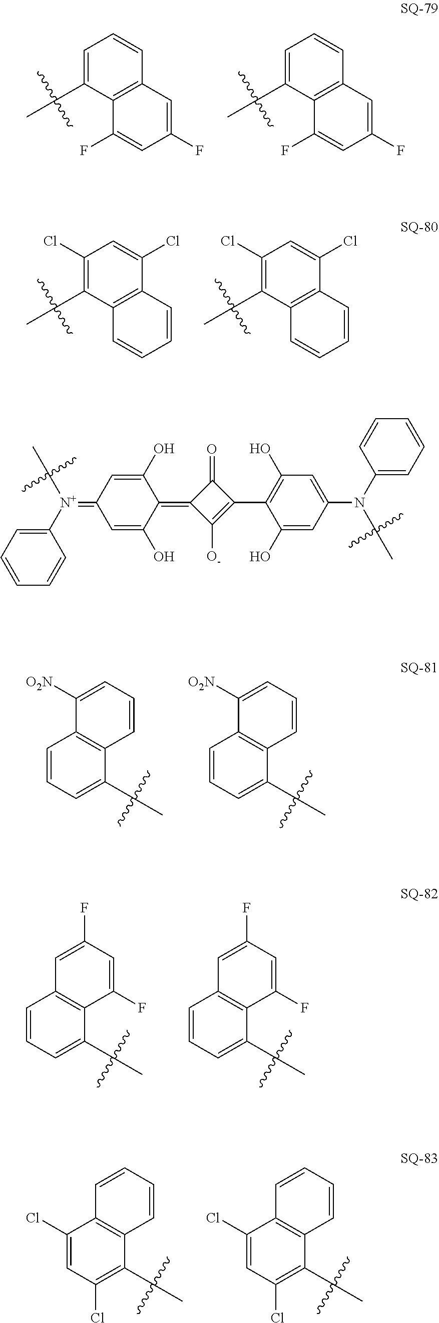

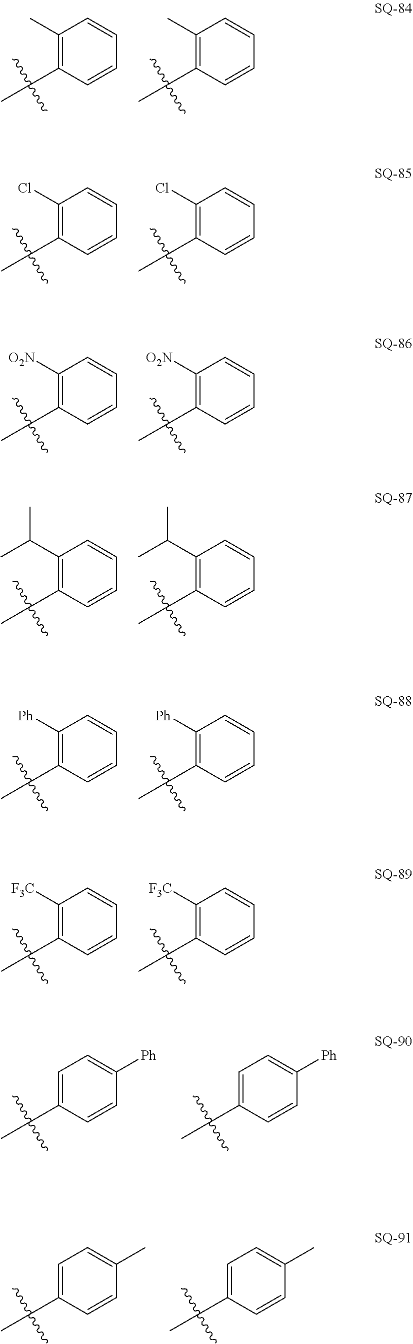

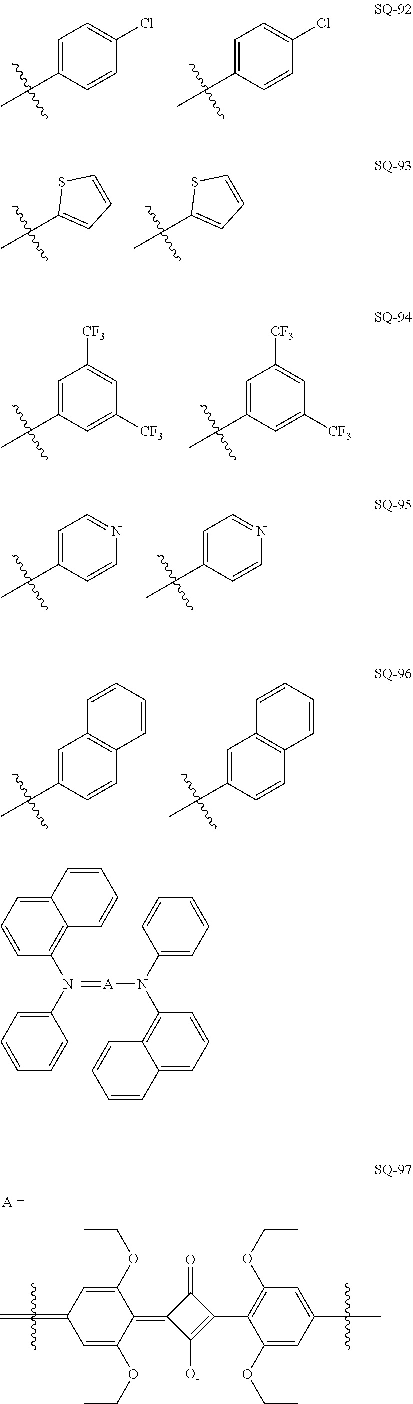

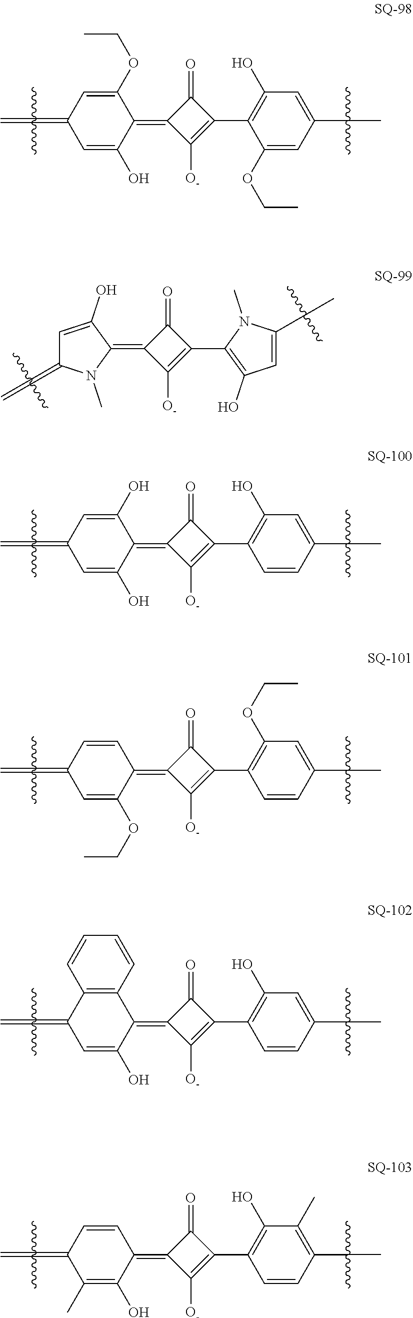

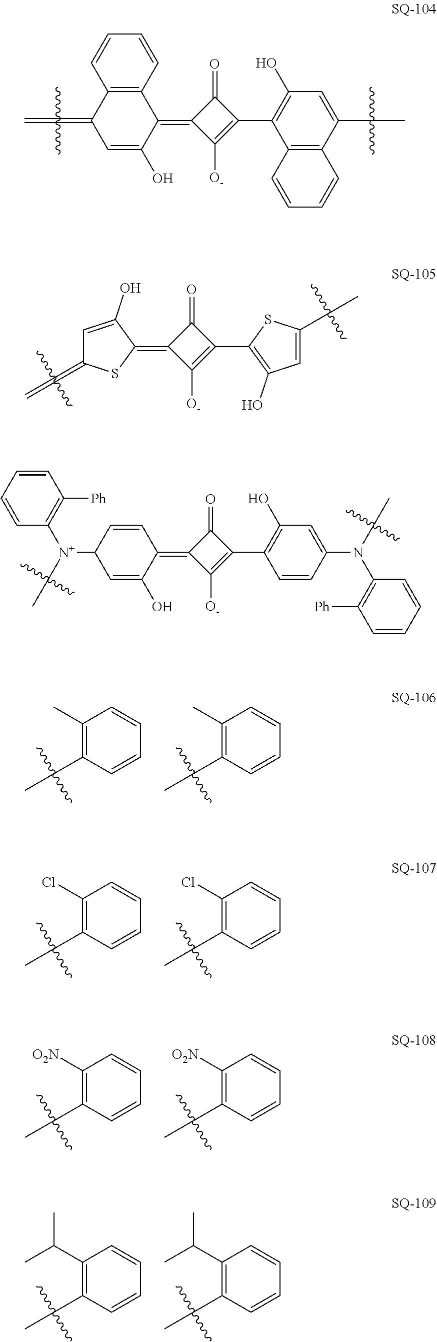

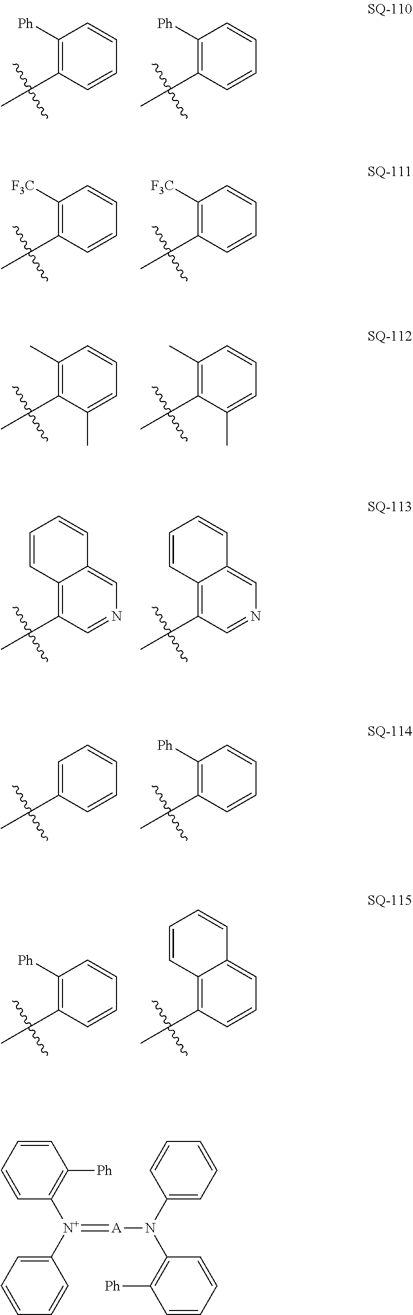

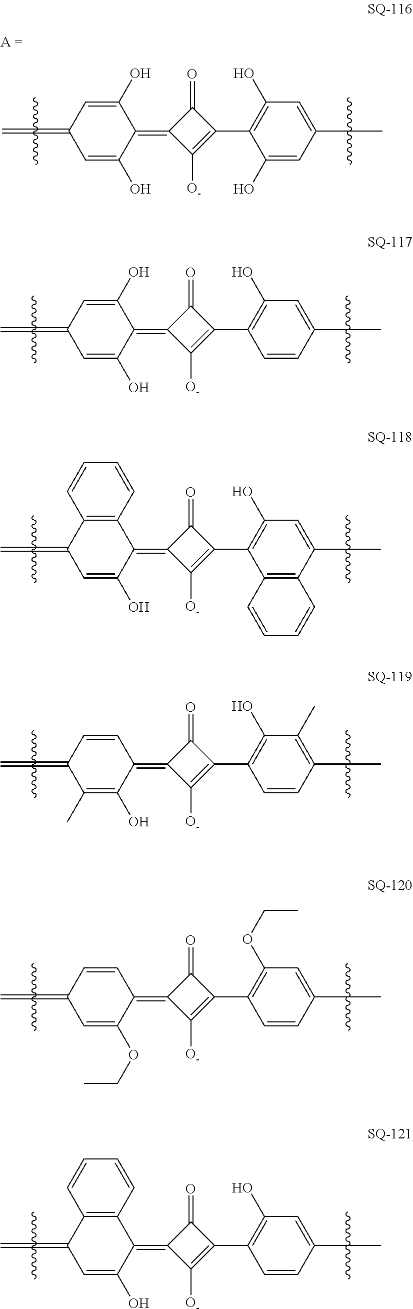

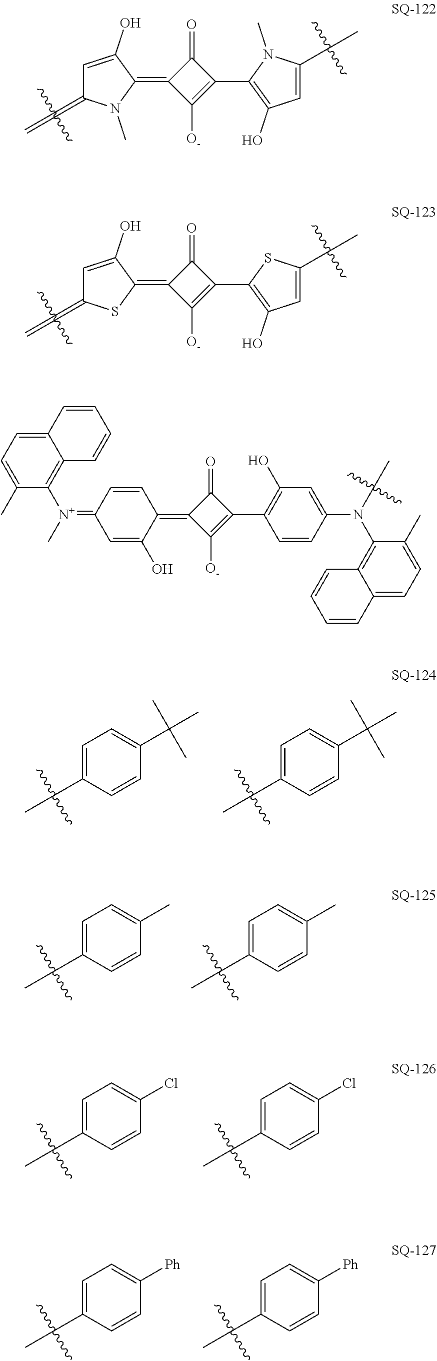

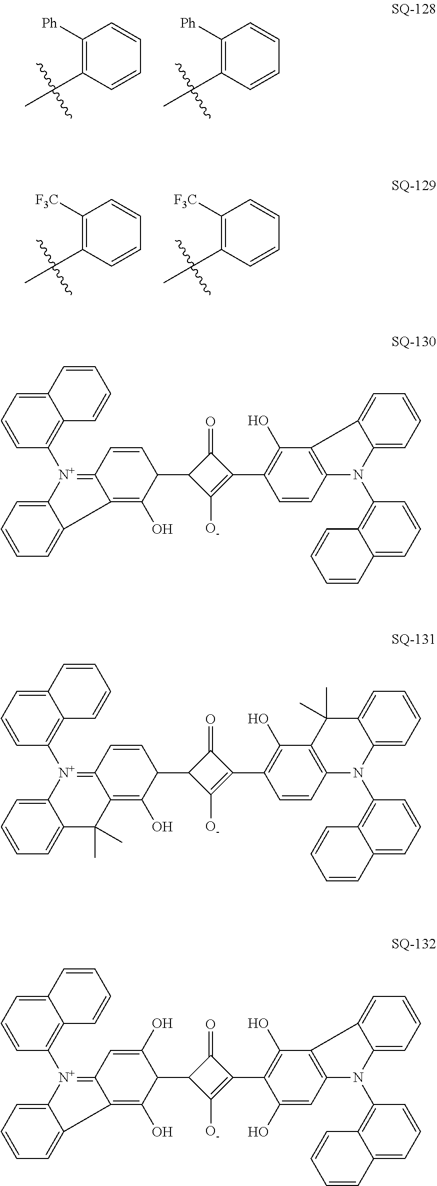

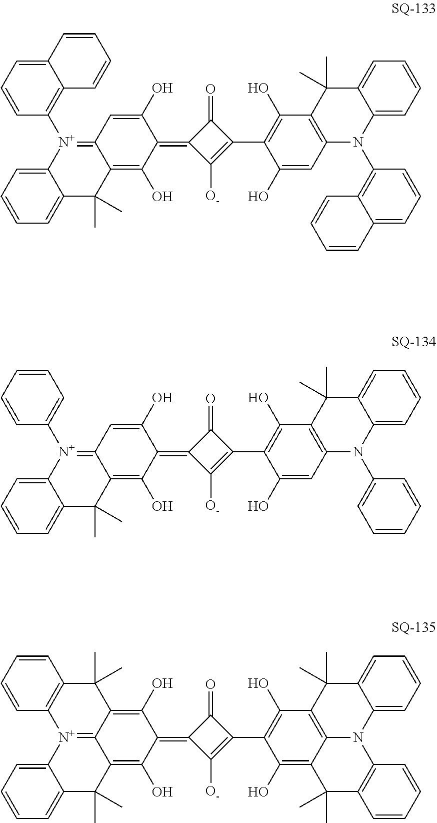

The green colorant used in the present invention may include a green colorant (hereinafter, also referred to as other green colorants) other than the above-described squarylium compound A. Examples thereof include phthalocyanine compounds such as Color Index (C. I.) Pigment Green 7, 10, 36, 37, 58, 59, 62, and 63. In addition, as the other green colorants, a halogenated zine phthalocyanine compound having an average number of halogen atoms in one molecule of 10 to 14, an average number of bromine atoms in one molecule of 8 to 12, and an average number of chlorine atoms in one molecule of 2 to 5 can also be used. Specific examples thereof include the compounds described in WO2015/118720A. In addition, as the other green colorants, a compound described in CN2010-6909027A, a phthalocyanine compound having phosphoric acid ester as a ligand, and the like can also be used.

The proportion of the squarylium compound A in the total amount of the green colorant is preferably 50 mass % or more and more preferably 70 mass % or more, and it is still more preferable that the green colorant is substantially composed of the squarylium compound A alone. The case where the green colorant is substantially composed of the squarylium compound A alone means that the proportion of the squarylium compound A in the total amount of the green colorant is 99 mass % or more, preferably 99.5 mass % or more, and it is still more preferable that the green colorant is composed of the squarylium compound A alone.

The content of the green colorant in the total solid content of the coloring composition is preferably 10 to 80 mass %. The lower limit is preferably 15 mass % or more and more preferably 20 mass % or more. The upper limit is preferably 70 mass % or less and more preferably 60 mass % or less. In addition, the content of the squarylium compound A in the total solid content of the coloring composition is preferably 10 to 80 mass %. The lower limit is preferably 15 mass % or more and more preferably 20 mass % or more. The upper limit is preferably 70 mass % or less and more preferably 60 mass % or less.

<<Other Colorants>>

The coloring composition according to the embodiment of the present invention can further contain a colorant having a color other than green. Examples of the other colorants include yellow colorants, orange colorants, red colorants, violet colorants, and blue colorants. The other colorants may be either a pigment or a dye.

As the pigment, an organic pigment is preferable. In addition, the average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the coloring composition is good. In the present invention, the primary particle diameter of the pigment can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is the arithmetic average value of the primary particle diameters with respect to 400 primary particles of the pigment. In addition, the primary particle of the pigment refers to a particle which is independent without aggregation.

The coloring composition according to the embodiment of the present invention preferably includes a yellow colorant as the other colorants, and more preferably includes a yellow pigment. According to this aspect, it is possible to suppress occurrence of aggregation, precipitation, or the like of the squarylium compound A during film formation and the like. Furthermore, it is easy to form a film having spectral characteristics suitable for green pixels. In addition, the content of the yellow pigment in the coloring composition is preferably 10 to 100 parts by mass with respect to 100 parts by mass of the green colorant. The upper limit is preferably 80 parts by mass or less, more preferably 70 parts by mass or less, and still more preferably 50 parts by mass or less. The lower limit is preferably 12.5 parts by mass or more, more preferably 14 parts by mass or more, and still more preferably 16 parts by mass or more.

Examples of the yellow colorant include an azo compound, a quinophthalone compound, an isoindolinone compound, an isoindoline compound, and an anthraquinone compound. Among these, from the reason that it is easy to form a film having spectral characteristics suitable for green pixels, an isoindoline compound is preferable.

Examples of the yellow pigment include Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and 231 (all of which are yellow pigments).

In addition, as the yellow pigment, pigments described in JP2017-201003A and pigments described in JP2017-197719A can be used. In addition, as the yellow pigment, a metal azo pigment which includes at least one kind of an anion selected from an azo compound represented by Formula (I) or an azo compound having a tautomeric structure of the azo compound represented by Formula (I), two or more kinds of metal ions, and a melamine compound can also be used.

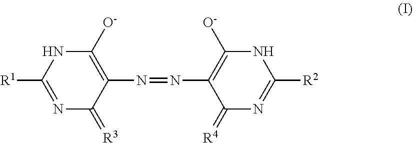

In the formula, R¹ and R² each independently represent —OH or —NR⁵R⁶, R³ and R⁴ each independently represent ═O or ═NR⁷, and R⁵ to R⁷ each independently represent a hydrogen atom or an alkyl group. The number of carbon atoms in the alkyl group represented by R⁵ to R⁷ is preferably 1 to 10, more preferably 1 to 6, and still more preferably 1 to 4. The alkyl group may be linear, branched, or cyclic, and is preferably linear or branched and more preferably linear. The alkyl group may have a substituent. The substituent is preferably a halogen atom, a hydroxy group, an alkoxy group, a cyano group, or an amino group.

With regard to the metal azo pigment, reference can be made to the description in paragraphs “0011” to “0062” and “0137” to “0276” of JP2017-171912A, paragraphs “0010” to “0062” and “0138” to “0295” of JP2017-171913A, paragraphs “0011” to “0062” and “0139” to “0190” of JP2017-171914A, and paragraphs “0010” to “0065” and “0142” to “0222” of JP2017-171915A, the contents of which are incorporated herein by reference.

In addition, as the yellow colorant, quinophthalone compounds described in paragraphs “0011” to “0034” of JP2013-054339A, or quinophthalone compounds described in paragraphs “0013” to “0058” of JP2014-026228A can also be used.

In addition, as the yellow colorant, compounds described in JP2018-062644A can also be used. These compounds can also be used as a pigment derivative.

Examples of chromatic colorants other than yellow include the following.

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C. I. Pigment Violet 1, 19, 23, 27, 32, 37, and 42 (all of which are violet pigments); and

C. I. Pigment Blue 1, 2, 15, 15:1, 15:2, 15:3, 15:4, 15:6, 16, 22, 60, 64, 66, 79, and 80 (all of which are blue pigments).

In addition, as the blue pigment, an aluminum phthalocyanine compound having a phosphorus atom can also be used. Specific examples thereof include compounds described in paragraphs “0022” to “0030” of JP2012-247591A and paragraph “0047” of JP2011-157478A.

As the red pigment, diketopyrrolopyrrole-based pigments described in JP2017-201384A, in which the structure has at least one substituted bromine atom, diketopyrrolopyrrole-based pigments described in paragraphs “0016” to “0022” of JP6248838B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As such a compound, a compound represented by Formula (DPP1) is preferable, and a compound represented by Formula (DPP2) is more preferable.

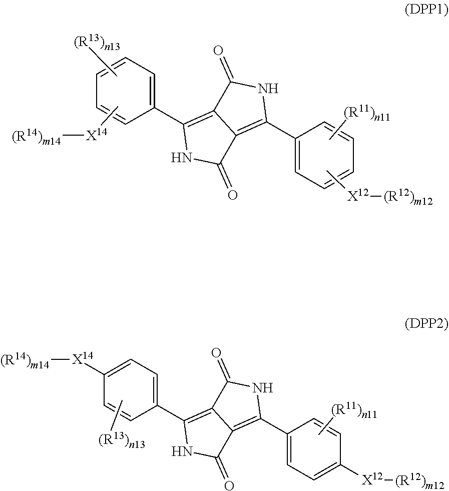

In the formulae, R¹¹ and R¹³ each independently represent a substituent, R¹² and R¹⁴ each independently represent a hydrogen atom, an alkyl group, an aryl group, or a heteroaryl group, nil and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Examples of the substituent represented by R¹¹ and R¹³ include the groups in a substituent T described later, and preferred specific examples thereof include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

As the dye, a known dye can be used without any particular limitation. Examples thereof include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

In addition, as the other colorants, thiazole compounds described in JP2012-158649A, azo compounds described in JP2011-184493A, or azo compounds described in JP2011-145540A can also be used.

In a case where the coloring composition according to the embodiment of the present invention contains other colorants, the content of the other colorants in the total solid content in the total solid content of the coloring composition according to the embodiment of the present invention is preferably 1 to 80 mass %. The lower limit is preferably 5 mass % or more and more preferably 10 mass % or more. The upper limit is preferably 70 mass % or less and more preferably 60 mass % or less. In addition, the total content of the green colorant and other colorants in the total solid content of the coloring composition is preferably 10 to 80 mass %. The lower limit is preferably 15 mass % or more and more preferably 20 mass % or more. The upper limit is preferably 70 mass % or less and more preferably 60 mass % or less.

<<Resin>>

The coloring composition according to the embodiment of the present invention contains a resin. The resin is blended in, for example, an application for dispersing particles such as a pigment in a coloring composition or an application as a binder. Mainly, a resin which is used for dispersing particles such as a pigment is also referred to as a dispersant. However, such applications of the resin are merely exemplary, and the resin can also be used for other purposes in addition to such applications.

The weight-average molecular weight (Mw) of the resin is preferably 3000 to 2000000. The upper limit is preferably 1000000 or less and more preferably 500000 or less. The lower limit is preferably 4000 or more and more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof. In addition, resins described in paragraphs “0041” to “0060” of JP2017-206689A, and resins described in paragraphs “0022” to “007” of JP2018-010856A can also be used.

In the present invention, as the resin, a resin having an acid group can be preferably used. According to this aspect, developability of the coloring composition can be improved, and pixels having excellent rectangularity can be easily formed. Examples of the acid group include a carboxyl group, a phosphoric acid group, a sulfo group, and a phenolic hydroxy group, and a carboxyl group is preferable. The resin having an acid group can be used, for example, as an alkali-soluble resin.

The resin having an acid group preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

It is also preferable that the resin having an acid group includes a repeating unit derived from a monomer component including a compound represented by Formula (ED1) and/or a compound represented by Formula (ED2) (hereinafter, these compounds may be referred to as an “ether dimer”).

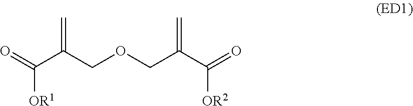

In Formula (ED1), R¹ and R² each independently represent a hydrogen atom or a hydrocarbon group having 1 to 25 carbon atoms which may have a substituent.

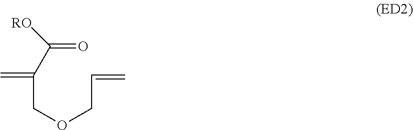

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

Specific examples of the ether dimer can be found in paragraph “0317” of JP2013-029760A, the content of which is incorporated herein by reference.

It is also preferable that the resin used in the present invention includes a repeating unit derived from a compound represented by Formula (X).

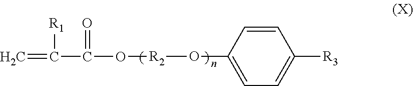

In Formula (X), R¹ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

With regard to the resin having an acid group, reference can be made to the description in paragraphs “0558” to “0571” of JP2012-208494A (paragraphs “0685” to “0700” of the corresponding US2012/0235099A) and the description in paragraphs “0076” to “0099” of JP2012-198408A, the contents of which are incorporated herein by reference. In addition, as the resin having an acid group, a commercially available product can also be used.

The acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. The weight-average molecular weight (Mw) of the resin having an acid group is preferably 5000 to 100000. In addition, the number-average molecular weight (Mn) of the resin having an acid group is preferably 1000 to 20000.

Examples of the resin having an acid group include resins having the following structures.

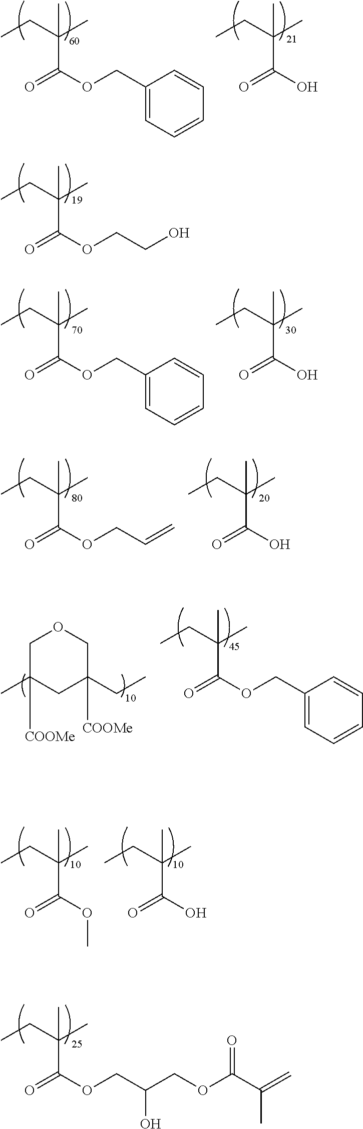

The coloring composition according to the embodiment of the present invention can include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group in the acidic dispersant (acidic resin) is preferably a carboxyl group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total content of the acid group and the basic group is 100 mol %. The basic group in the basic dispersant is preferably an amino group.

It is preferable that the resin used as a dispersant includes a repeating unit having an acid group. In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraphs “0025” to “0094” of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraphs “0102” to “0166” of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraphs “0196” to “0209” of JP2013-043962A.

In addition, the above-described resin (alkali-soluble resin) having an acid group can also be used as a dispersant.

In addition, it is also preferable that the resin used as a dispersant is a resin including a repeating unit having an ethylenically unsaturated bonding group in the side chain. The content of the repeating unit having an ethylenically unsaturated bonding group in the side chain is preferably 10 mol % or more, more preferably 10 to 80 mol %, and still more preferably 20 to 70 mol % with respect to all the repeating units of the resin.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. In addition, pigment dispersants described in paragraphs “0041” to “0130” of JP2014-130338A can also be used, the contents of which are incorporated herein by reference. The resin described as a dispersant can be used for an application other than the dispersant. For example, the resin can also be used as a binder.

The content of the resin in the total solid content of the coloring composition is preferably 5 to 50 mass %. The lower limit is preferably 10 mass % or more and more preferably 15 mass % or more. The upper limit is preferably 40 mass % or less, more preferably 35 mass % or less, and still more preferably 30 mass % or less. In addition, the content of the resin (alkali-soluble resin) having an acid group in the total solid content of the coloring composition is preferably 5 to 50 mass %. The lower limit is preferably 10 mass % or more and more preferably 15 mass % or more. The upper limit is preferably 40 mass % or less, more preferably 35 mass % or less, and still more preferably 30 mass % or less. In addition, from the reason that excellent developability is easily obtained, the content of the resin (alkali-soluble resin) having an acid group in the total amount of the resin is preferably 30 mass % or more, more preferably 50 mass % or more, still more preferably 70 mass % or more, and particularly preferably 80 mass % or more. The upper limit may be 100 mass %, 95 mass %, or 90 mass % or less.

In addition, from the viewpoint of curability, developability, and film-forming property, the total content of the polymerizable compound and resin in the total solid content of the coloring composition is preferably 10 to 65 mass %. The lower limit is preferably 15 mass % or more, more preferably 20 mass % or more, and still more preferably 30 mass % or more. The upper limit is preferably 60 mass % or less, more preferably 50 mass % or less, and still more preferably 40 mass % or less. In addition, the coloring composition according to the embodiment of the present invention preferably contains 30 to 300 parts by mass of the resin with respect to 100 parts by mass of the polymerizable compound. The lower limit is preferably 50 parts by mass or more and more preferably 80 parts by mass or more. The upper limit is preferably 250 parts by mass or less and more preferably 200 parts by mass or less.

<<Pigment Derivative>>

The coloring composition according to the embodiment of the present invention can contain a pigment derivative. According to this aspect, storage stability of the coloring composition can be further improved. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

P [symbol] L-(X)ₙ)ₘ (B1)

In Formula (B1), P represents a coloring agent structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

Examples of the coloring agent structure represented by P include a pyrrolopyrrole coloring agent structure, a diketopyrrolopyrrole coloring agent structure, a quinacridone coloring agent structure, an anthraquinone coloring agent structure, a dianthraquinone coloring agent structure, a benzoisoindole coloring agent structure, a thiazine indigo coloring agent structure, an azo coloring agent structure, a quinophthalone coloring agent structure, a phthalocyanine coloring agent structure, a naphthalocyanine coloring agent structure, a dioxazine coloring agent structure, a perylene coloring agent structure, a perinone coloring agent structure, a benzimidazolone coloring agent structure, a benzothiazole coloring agent structure, a benzimidazole coloring agent structure, and a benzoxazole coloring agent structure.

Examples of the linking group represented by L include a hydrocarbon group, a heterocyclic group, —NR—, —SO₂—, —S—, —O—, —CO—, or a group of a combination of these groups. R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and heterocyclic group represented by R^{X1} to R^{X6} may further have a substituent. As the substituent which may be further included, a halogen atom is preferable and a fluorine atom is more preferable. Examples of the basic group represented by X include an amino group. Examples of the salt structure represented by X include a salt of the acid group or the basic group described above.

Examples of the pigment derivative include compounds having the following structures. In addition, for example, compounds described in JP1981-118462A (JP-S56-118462A), JP1988-264674A (JP-S63-264674A), JP1989-217077A (JP-H1-217077A), JP1991-009961A (JP-H3-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, and paragraph “0082” of WO2017/038252A can be used, the contents of which are incorporated herein by reference.

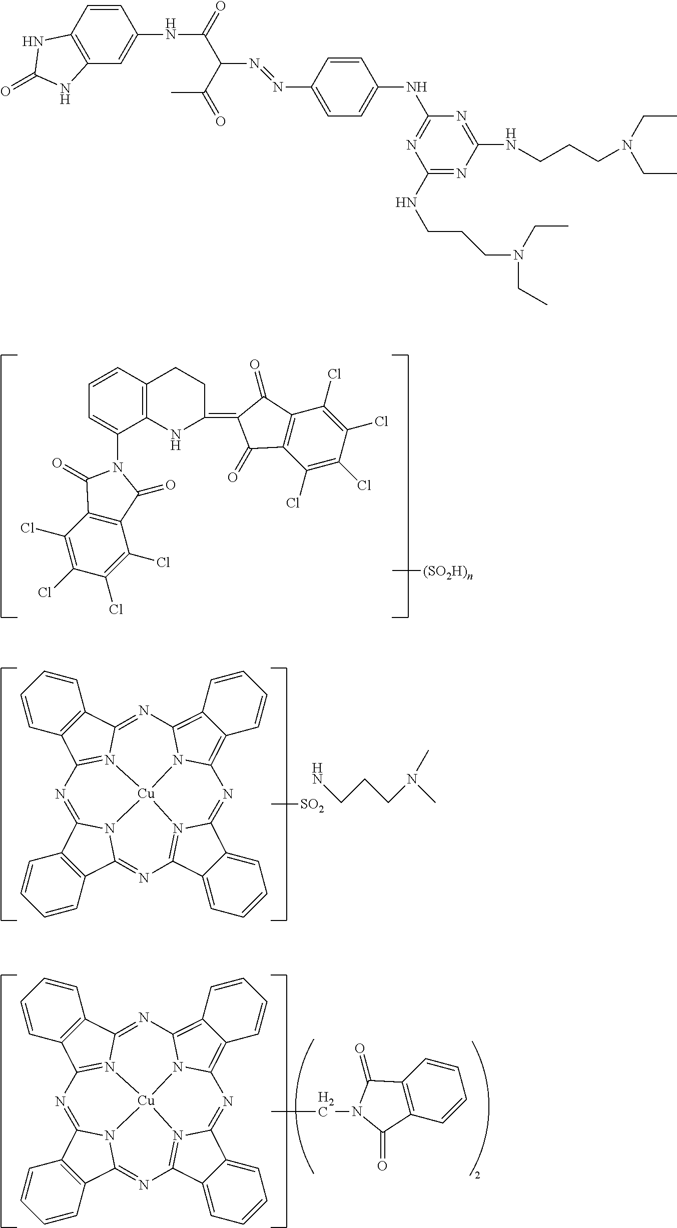

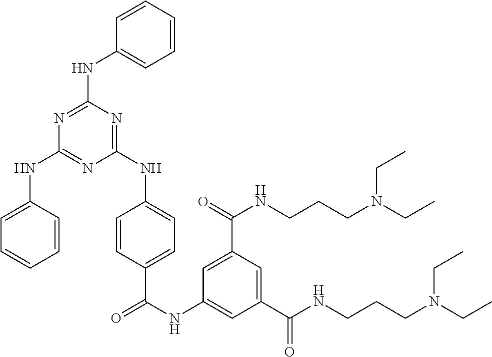 [SMILES: CCN(CC)CCCNC(=O)c1cc(NC(=O)c2ccc(Nc3nc(Nc4ccccc4)nc(Nc4ccccc4)n3)cc2)cc(C(=O)NCCCN(CC)CC)c1]

The content of the pigment derivative in the total solid content of the coloring composition is preferably 0.3 to 20 mass %. The lower limit is preferably 0.6 mass % or more and more preferably 0.9 mass % or more. The upper limit is preferably 15 mass % or less, more preferably 12.5 mass % or less, and still more preferably 10 mass % or less.

In addition, the content of the pigment derivative is preferably 1 to 30 parts by mass with respect to 100 parts by mass of the pigment. The lower limit is preferably 2 parts by mass or more and more preferably 3 parts by mass or more. The upper limit is preferably 25 parts by mass or less, more preferably 20 parts by mass or less, and still more preferably 15 parts by mass or less. As the pigment derivative, one kind may be used alone, or two or more kinds may be used in combination. In a case where two or more kinds of pigment derivatives are used in combination, it is preferable that the total content of the two or more kinds of pigment derivatives is within the above-described range.

<<Polymerizable Compound>>

It is preferable that the coloring composition according to the embodiment of the present invention contains a polymerizable compound. As the polymerizable compound, a known compound which is cross-linkable by a radical, an acid, or heat can be used. In the present invention, the polymerizable compound is preferably, for example, a compound having an ethylenically unsaturated bonding group. Examples of the ethylenically unsaturated bonding group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bonding groups, more preferably a compound including 3 to 15 ethylenically unsaturated bonding groups, and still more preferably a compound having 3 to 6 ethylenically unsaturated bonding groups. In addition, the polymerizable compound is preferably a 3- to 15-functional (meth)acrylate compound and more preferably a 3- to 6-functional (meth)acrylate compound. Specific examples of the polymerizable compound include compounds described in paragraphs “0095” to “0108” of JP2009-288705A, paragraph “0227” of JP2013-029760A, paragraphs “0254” to “0257” of JP2008-292970A, paragraphs “0034” to “0038” of JP2013-253224A, paragraph “0477” of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which the (meth)acryloyl group of these compounds is bonded through an ethylene glycol and/or a propylene glycol residue (for example, SR454 and SR499 which are commercially available from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in an unexposed area is easily removed during development and the generation of the development residue can be suppressed. Examples of the acid group include a carboxyl group, a sulfo group, and a phosphoric acid group, and a carboxyl group is preferable. Examples of a commercially available product of the polymerizable compound having an acid group include ARONIX M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a 3- to 6-functional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having four ethyleneoxy groups, and KAYARAD TPA-330 manufactured by Nippon Kayaku Co., Ltd, which is a trifunctional (meth)acrylate having three isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), and JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The content of the polymerizable compound in the total solid content of the coloring composition is preferably 0.1 to 50 mass %. The lower limit is more preferably 0.5 mass % or more and still more preferably 1 mass % or more. The upper limit is more preferably 45 mass % or less and still more preferably 40 mass % or less. The polymerizable compound may be used singly or in combination of two or more kinds thereof. In a case where two or more kinds of polymerizable compounds are used in combination, it is preferable that the total of the two or more kinds of polymerizable compounds is within the above-described range.

<<Photopolymerization Initiator>>

It is preferable that the coloring composition according to the embodiment of the present invention includes a photopolymerization initiator. In particular, in a case where the coloring composition according to the embodiment of the present invention includes the polymerizable compound, it is preferable that the coloring composition according to the embodiment of the present invention further includes a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. The details of the photopolymerization initiator can be found in paragraphs “0065” to “0111” of JP2014-130173A and in JP6301489B, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF). Examples of a commercially available product of the α-aminoketone compound include IRGACURE-907, IRGACURE-369, IRGACURE-379, and IRGACURE-379EG (all of which are manufactured by BASF). Examples of a commercially available product of the acylphosphine compound include IRGACURE-819, and DAROCUR-TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2000-080068A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, and the compounds described in paragraphs “0025” to “0038” of WO2017/164127A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no coloring property or a compound having high transparency and being resistant to discoloration. Examples of a commercially available product thereof include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include compounds described in JP2014-137466A. The content thereof is incorporated herein by reference.

In the present invention, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A. The contents thereof are incorporated herein by reference.

In the present invention, an oxime compound having a nitro group can be used as the photopolymerization initiator. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by ADEKA Corporation).

In the present invention, an oxime compound having a benzofuran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

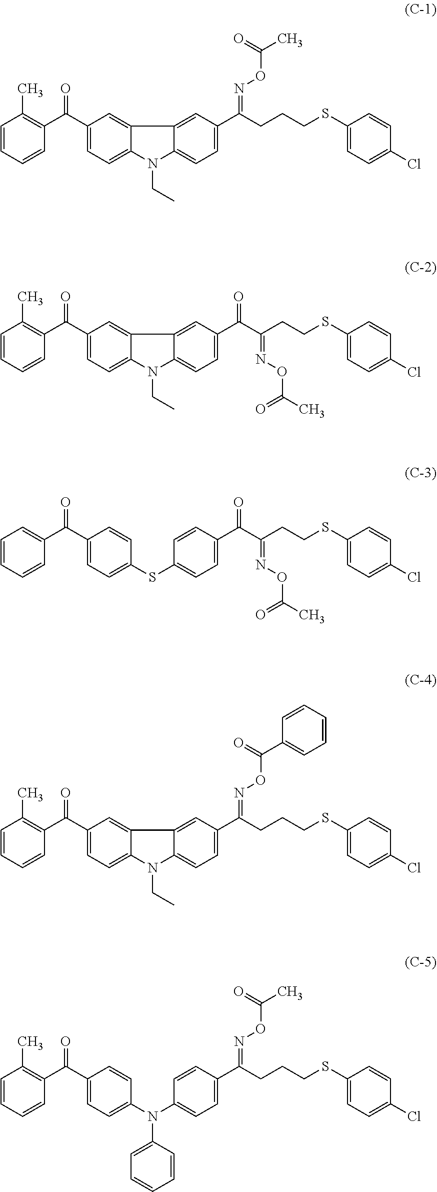 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1]

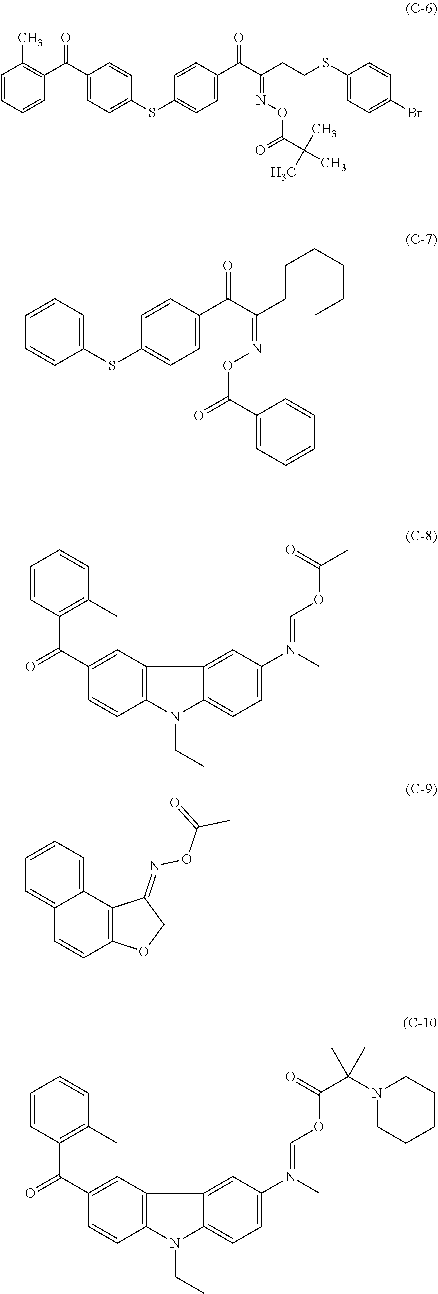

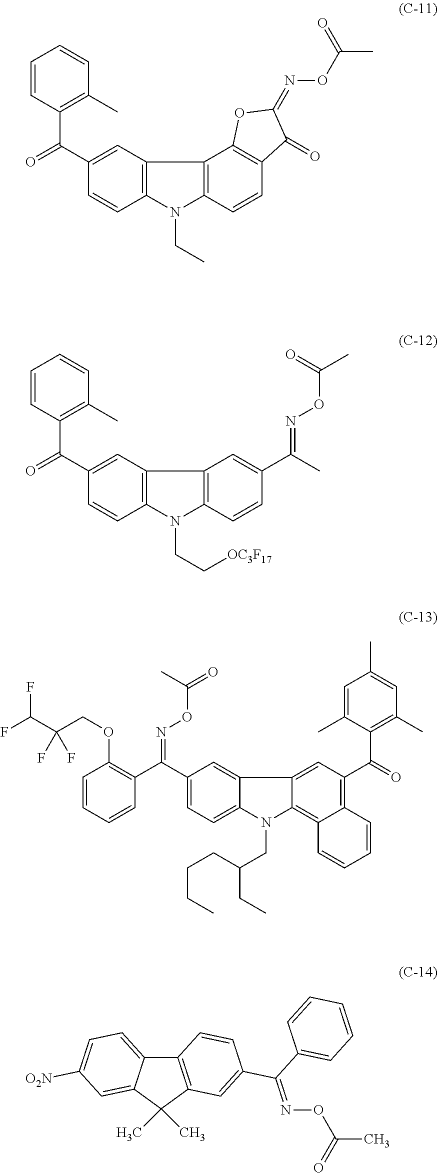

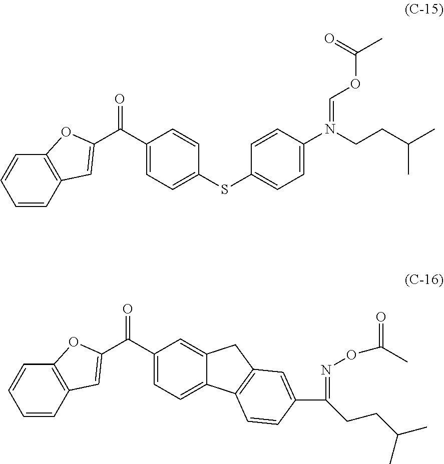

The oxime compound is preferably a compound having a maximum absorption wavelength in a wavelength range of 350 to 500 nm and more preferably a compound having a maximum absorption wavelength in a wavelength range of 360 to 480 nm. In addition, from the viewpoint of sensitivity, the molar absorption coefficient of the oxime compound at a wavelength of 365 nm or at a wavelength of 405 nm is preferably high, more preferably 1,000 to 300,000, still more preferably 2,000 to 300,000, and particularly preferably 5,000 to 200.000. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

In the present invention, as the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or more functional photoradical polymerization initiator include dimers of the oxime compounds described in JP2010-527339A, JP2011-524436A, WO2015/004565A, paragraphs “0407” to “0412” of JP2016-532675A, and paragraphs “0039” to “0055” of WO2017/033680A; the compound (E) and compound (G) described in JP2013-522445A; Cmpd 1 to 7 described in WO2016/034963A; the oxime ester photoinitiators described in paragraph “0007” of JP2017-523465A; the photoinitiators described in paragraphs “0020” to “0033” of JP2017-167399A; and the photopolymerization initiator (A) described in paragraphs “0017” to “0026” of JP2017-151342A.

In a case where the coloring composition according to the embodiment of the present invention contains a photopolymerization initiator, the content of the photopolymerization initiator in the total solid content of the coloring composition according to the embodiment of the present invention is preferably 0.1 to 30 mass %. The lower limit is preferably 0.5 mass % or more and more preferably 1 mass % or more. The upper limit is preferably 20 mass % or less and more preferably 15 mass % or less. In the coloring composition according to the embodiment of the present invention, the photopolymerization initiator may be used singly or in combination of two or more kinds thereof. In a case where two or more kinds thereof are used, the total content thereof is preferably within the above-described range.

<<Compound Having Cyclic Ether Group>>

The coloring composition according to the embodiment of the present invention can contain a compound having a cyclic ether group. Examples of the cyclic ether group include an epoxy group and an oxetanyl group. The compound having a cyclic ether group is preferably a compound having an epoxy group. Examples of the compound having an epoxy group include a compound having one or more epoxy groups in one molecule, and a compound two or more epoxy groups in one molecule is preferable. It is preferable to have 1 to 100 epoxy groups in one molecule. The upper limit of the number of epoxy groups may be, for example, 10 or less or 5 or less. The lower limit of the number of epoxy groups is preferably 2 or more. As the compound having an epoxy group, compounds described in paragraphs “0034” to “0036” of JP2013-011869A, paragraphs “0147” to “0156” of JP2014-043556A, and paragraphs “0085” to “0092” of JP2014-089408A, and compounds described in JP2017-179172A can also be used. The contents thereof are incorporated herein by reference.

The compound having an epoxy group may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). The weight-average molecular weight of the compound having an epoxy group is preferably 200 to 100000 and more preferably 500 to 50000. The upper limit of the weight-average molecular weight is preferably 10000 or less, more preferably 5000 or less, and still more preferably 3000 or less.

As the compound having an epoxy group, an epoxy resin can be preferably used. Examples of the epoxy resin include an epoxy resin which is a glycidyl etherified product of a phenol compound, an epoxy resin which is a glycidyl etherified product of various novolak resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

In a case where the coloring composition according to the embodiment of the present invention contains a compound having a cyclic ether group, the content of the compound having a cyclic ether group in the total solid content of the coloring composition is preferably 0.1 to 20 mass %. The lower limit is, for example, preferably 0.5 mass % or more and more preferably 1 mass % or more. The upper limit is, for example, preferably 15 mass % or less and still more preferably 10 mass % or less. The compound having a cyclic ether group may be used singly or in combination of two or more kinds thereof. In a case of using two or more kinds thereof, the total content thereof is preferably within the above-described range.

<<Near-infrared Absorber>>

The coloring composition according to the embodiment of the present invention can further contain a near-infrared absorber. The near-infrared absorber is preferably a compound having a maximum absorption wavelength in a wavelength range of more than 700 nm and 1800 nm or less. In addition, in the near-infrared absorber, a ratio A¹/A², which is a ratio of an absorbance A1 at a wavelength of 500 nm to an absorbance A² at the maximum absorption wavelength, is preferably 0.08 or less and more preferably 0.04 or less.

Examples of the near-infrared absorber include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a metal oxide, and a metal boride. Examples of the pyrrolopyrrole compound include compounds described in paragraphs “0016” to “0058” of JP2009-263614A, compounds described in paragraphs “0037” to “0052” of JP2011-068731A, and compounds described in paragraphs “0010” to “0033” of WO2015/166873A. Examples of the squarylium compound include compounds described in paragraphs “0044” to “0049” of JP2011-208101A, compounds described in paragraphs “0060” and “0061” of JP6065169B, compounds described in paragraph “0040” of WO2016/181987A, compounds described in JP2015-176046A, compounds described in paragraph “0072” of WO2016/190162A, compounds described in paragraphs “0196” to “0228” of JP2016-074649A, compounds described in paragraph “0124” of JP2017-067963A, compounds described in WO2017/135359A, compounds described in JP2017-114956A, compounds described in JP6197940B, and compounds described in WO2016/120166A. Examples of the cyanine compound include compounds described in paragraphs “0044” and “0045” of JP2009-108267A, compounds described in paragraphs “0026” to “0030” of JP2002-194040A, compounds described in JP2015-172004A, compounds described in JP2015-172102A, compounds described in JP2008-088426A, and compounds described in paragraph “0090” of WO2016/190162A. Examples of the croconium compound include compounds described in JP2017-082029A. Examples of the iminium compound include compounds described in JP2008-528706A, compounds described in JP2012-012399A, compounds described in JP2007-092060A, and compounds described in paragraphs “0048” to “0063” of WO2018/043564A. Examples of the phthalocyanine compound include compounds described in paragraph “0093” of JP2012-077153A, oxytitanium phthalocyanine described in JP2006-343631A, and compounds described in paragraphs “0013” to “0029” of JP2013-195480A. Examples of the naphthalocyanine compound include compounds described in paragraph “0093” of JP2012-077153A. Examples of the metal oxide include indium tin oxide, antimony tin oxide, zinc oxide, Al-doped zinc oxide, fluorine-doped tin dioxide, niobium-doped titanium dioxide, and tungsten oxide. The details of tungsten oxide can be found in paragraph “0080” of JP2016-006476A, the content of which is incorporated herein by reference. Examples of the metal boride include lanthanum boride. Examples of a commercially available product of lanthanum boride include LaB₆—F (manufactured by JAPAN NEW METALS CO., LTD.). In addition, as the metal boride, compounds described in WO2017/119394A can also be used. Examples of a commercially available product of indium tin oxide include F-ITO (manufactured by DOWA HIGHTECH CO., LTD.).

In addition, as the near-infrared absorber, squarylium compounds described in JP2017-197437A, squarylium compounds described in paragraphs “0090” to “0107” of WO2017/213047A, pyrrole ring-containing compounds described in paragraphs “0019” to “0075” of JP2018-054760A, pyrrole ring-containing compounds described in paragraphs “0078” to “0082” of JP2018-040955A, pyrrole ring-containing compounds described in paragraphs “0043” to “0069” of JP2018-002773A, squarylium compounds having an aromatic ring at the amide α-position described in paragraphs “0024” to “0086” of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029A, asymmetric compounds described in paragraphs “0027” to “0114” of JP2017-068120A, pyrrole ring containing compounds (carbazole type) described in JP2017-067963A, and phthalocyanine compounds described in JP6251530B.

In a case where the coloring composition according to the embodiment of the present invention contains a near-infrared absorber, the content of the near-infrared absorber in the total solid content of the coloring composition is preferably 1 mass % or more, more preferably 5 mass % or more, and particularly preferably 10 mass % or more. The upper limit is not particularly limited, but is preferably 70 mass % or less, more preferably 65 mass % or less, and still more preferably 60 mass % or less.

In addition, it is also possible that the coloring composition according to the embodiment of the present invention does not substantially contain the near-infrared absorber. The case where the coloring composition according to the embodiment of the present invention does not substantially contain the near-infrared absorber means that the content of the near-infrared absorber in the total solid content of the coloring composition according to the embodiment of the present invention is preferably 0.1 mass % or less, more preferably 0.05 mass % or less, and particularly preferably 0 mass %.

<<Silane Coupling Agent>>

The coloring composition according to the embodiment of the present invention can contain a silane coupling agent. According to this aspect, adhesiveness of a film to be obtained with a support can be further improved. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraphs “0018” to “0036” of JP2009-288703A and the compounds described in paragraphs “0056” to “0066” of JP2009-242604A, the contents of which are incorporated herein by reference.

The content of the silane coupling agent in the total solid content of the coloring composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, the total content thereof is preferably within the above-described range.

<<Organic Solvent>>

The coloring composition according to the embodiment of the present invention contains an organic solvent. Basically, the organic solvent is not particularly limited as long as it satisfies the solubility of the respective components and the application properties of the coloring composition. Examples of the organic solvent include an ester solvent, a ketone solvent, an alcohol solvent, an amide solvent, an ether solvent, and a hydrocarbon solvent. With regard to details thereof, reference can be made to the description in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include isomers (compounds having the same number of atoms and different structures). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

The content of the organic solvent in the coloring composition is preferably 10 to 95 mass %, more preferably 20 to 90 mass %, and still more preferably 30 to 90 mass %.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition according to the embodiment of the present invention, and may be incorporated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, coloring composition produced by mixing these compounds, or the like.

<<Polymerization Inhibitor>>

The coloring composition according to the embodiment of the present invention can contain a polymerization inhibitor. Examples of the polymerization inhibitor include hydroquinone, p-methoxyphenol, di-tert-butyl-p-cresol, pyrogallol, t-butyl catechol, benzoquinone, 4,4′-thiobis(3-methyl-6-tert-butylphenol), 2,2′-methylenebis(4-methyl-6-tert-butylphenol), and an N-nitrosophenylhydroxyamine salt (an ammonium salt, a cerous salt, or the like). Among these, p-methoxyphenol is preferable. The content of the polymerization inhibitor in the total solid content of the coloring composition is preferably 0.0001 to 5 mass %.

<<Surfactant>>

The coloring composition according to the embodiment of the present invention can contain a surfactant. As the surfactant, various surfactants such as a fluorine surfactant, a nonionic surfactant, a cationic surfactant, an anionic surfactant, or a silicon-based surfactant can be used. With regard to the surfactant, reference can be made to the description in paragraphs “0238” to “0245” of WO2015/166779A, the contents of which are incorporated herein by reference.

In the present invention, it is preferable that the surfactant is a fluorine surfactant. By containing a fluorine surfactant in the coloring composition, liquid characteristics (particularly, fluidity) are further improved, and liquid saving properties can be further improved. In addition, it is possible to form a film with a small thickness unevenness.

The fluorine content in the fluorine surfactant is preferably 3 to 40 mass %, more preferably 5 to 30 mass %, and particularly preferably 7 to 25 mass %. The fluorine surfactant in which the fluorine content is within the above-described range is effective in terms of the evenness of the thickness of the coating film or liquid saving properties and the solubility of the surfactant in the coloring composition is also good.

Examples of the fluorine surfactant include surfactants described in paragraphs “0060” to “0064” of JP2014-041318A (paragraphs “0060” to “0064” of the corresponding WO2014/017669A) and the like, and surfactants described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine surfactant, a polymer of a fluorine atom-containing vinyl ether compound having a fluorinated alkyl group or a fluorinated alkylene ether group, and a hydrophilic vinyl ether compound can be preferably used. With regard to such a fluorine surfactant, reference can be made to the description in JP2016-216602A, the contents of which are incorporated herein by reference.

As the fluorine surfactant, a block polymer can also be used. Examples thereof include compounds described in JP2011-089090A. As the fluorine surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. For example, the following compound can also be used as the fluorine surfactant used in the present invention.

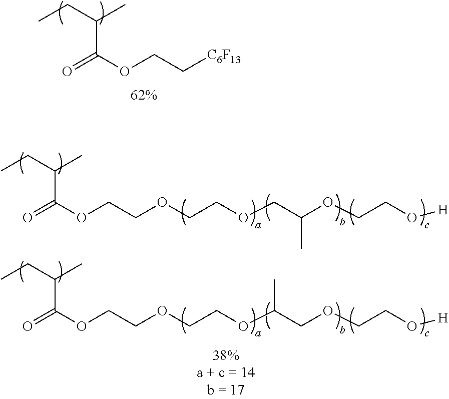

The weight-average molecular weight of the compound is preferably 3000 to 50000 and, for example, 14000. In the compound, “%” representing the proportion of a repeating unit is mol %.

In addition, as the fluorine surfactant, a fluorine-containing polymer including a repeating unit having an ethylenically unsaturated bonding group in the side chain can be used. Specific examples thereof include compounds described in paragraphs “0050” to “0090” and paragraphs “0289” to “0295” of JP2010-164965A, and for example, MEGAFACE RS-101, RS-102, RS-718K, and RS-72-K manufactured by DIC Corporation. As the fluorine surfactant, compounds described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

The content of the surfactant in the total solid content of the coloring composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. With regard to details thereof, reference can be made to the description in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Specific examples of the ultraviolet absorber include compounds having the following structures. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs “0049” to “0059” of JP6268967B can also be used.

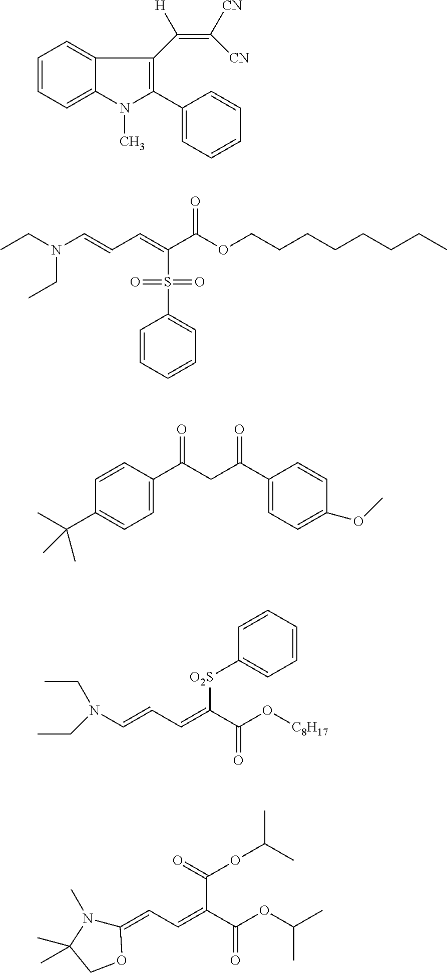

The content of the ultraviolet absorber in the total solid content of the coloring composition is preferably 0.01 to 10 mass % and more preferably 0.01 to 5 mass %. In the present invention, the ultraviolet absorber may be used singly or in combination of two or more kinds thereof. In a case where two or more kinds thereof are used, the total content thereof is preferably within the above-described range.

<<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraphs “0023” to “0048” of JP6268967B can also be used.

The content of the antioxidant in the total solid content of the coloring composition is preferably 0.01 to 20 mass % and more preferably 0.3 to 15 mass %. In the present invention, the antioxidant may be used singly or in combination of two or more kinds thereof. In a case where two or more kinds thereof are used, the total content thereof is preferably within the above-described range.

<<Other Components>>

Optionally, the coloring composition according to the embodiment of the present invention may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraphs “0183” and later of JP2012-003225A (corresponding to paragraph “0237” of US2013/0034812A) and paragraphs “0101” to “0104” and “0107” to “0109” of JP2008-250074A, the content of which is incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation).

In addition, in order to adjust the refractive index of the film to be obtained, the coloring composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and most preferably 5 to 50 nm. The metal oxide may have a core-shell structure, and in this case, the core portion may be hollow.

In addition, the coloring composition according to the embodiment of the present invention may include a light-resistance improver. Examples of the light-resistance improver include the compounds described in paragraphs “0036” and “0037” of JP2017-198787A, the compounds described in paragraphs “0029” to “0034” of JP2017-146350A, the compounds described in paragraphs “0036” and “0037”, and “0049” to “0052” of JP2017-129774A, the compounds described in paragraphs “0031” to “0034”, “0058”, and “0059” of JP2017-129674A, the compounds described in paragraphs “0036” and “0037”, and “0051” to “0054” of JP2017-122803A, the compounds described in paragraphs “0025” to “0039” of WO2017/164127A, the compounds described in paragraphs “0034” to “0047” of JP2017-186546A, the compounds described in paragraphs “0019” to “0041” of JP2015-025116A, the compounds described in paragraphs “0101” to “0125” of JP2012-145604A, the compounds described in paragraphs “0018” to “0021” of JP2012-103475A, the compounds described in paragraphs “0015” to “0018” of JP2011-257591A, the compounds described in paragraphs “0017” to “0021” of JP2011-191483A, the compounds described in paragraphs “0108” to “0116” of JP2011-145668A, and the compounds described in paragraphs “0103” to “0153” of JP2011-253174A.

For example, in a case where a film is formed by application, the viscosity (25° C.) of the coloring composition according to the embodiment of the present invention is preferably 1 to 100 mPa×s. The lower limit is more preferably 2 mPa×s or more and still more preferably 3 mPa×s or more. The upper limit is more preferably 50 mPa×s or less, still more preferably 30 mPa×s or less, and particularly preferably 15 mPa×s or less.

In the coloring composition according to the embodiment of the present invention, the content of free metal which is not bonded to or coordinated with a pigment or the like is preferably 100 ppm or less, more preferably 50 ppm or less, and still more preferably 10 ppm or less, it is particularly preferable to not contain the free metal substantially. According to this aspect, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can be obtained. Examples of the types of the above-described free metals include Na, K, Ca, Sc, Ti, Mn, Cu, Zn, Fe, Cr, Fe, Co, Mg, Al, Sn, Zr, Ga, Ge, Ag, Au, Pt, Cs, and Bi. In addition, in the coloring composition according to the embodiment of the present invention, the content of free halogen which is not bonded to or coordinated with a pigment or the like is preferably 100 ppm or less, more preferably 50 ppm or less, and still more preferably 10 ppm or less, it is particularly preferable to not contain the free halogen substantially. Examples of a method for reducing free metals and halogens in the coloring composition include washing with ion exchange water, filtration, ultrafiltration, and purification with an ion exchange resin.

It is also preferable that the coloring composition according to the embodiment of the present invention does not substantially include terephthalic acid ester.

<Storage Container>

A storage container of the coloring composition according to the embodiment of the present invention is not particularly limited, and a known storage container can be used. In addition, as the storage container, in order to suppress infiltration of impurities into the raw materials or the coloring composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-12335A.

<Method of Preparing Coloring Composition>

The coloring composition according to the embodiment of the present invention can be prepared by mixing the above-described components with each other. During the preparation of the coloring composition, all the components may be dissolved or dispersed in an organic solvent at the same time to prepare the coloring composition. Optionally, two or more solutions or dispersion liquids in which the respective components are appropriately blended may be prepared, and the solutions or dispersion liquids may be mixed with each other during use (during application) to prepare the coloring composition.

In addition, in the preparation of the coloring composition, a process of dispersing the pigment is preferably included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph “0022” of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the preparation of the coloring composition, it is preferable that the coloring composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 m, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Advantec Toyo Kaisha, Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Film>

The film according to the embodiment of the present invention is a film obtained from the above-described coloring composition according to the embodiment of the present invention. The film according to the embodiment of the present invention can be used for a color filter or the like. Specifically, the film according to the embodiment of the present invention can be preferably used as a colored layer (pixel) of a color filter, and more specifically, the film according to the embodiment of the present invention can be preferably used as a green-colored layer (green pixel) of a color filter. The thickness of the film according to the embodiment of the present invention can be appropriately adjusted according to the purpose. For example, the thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

<Color Filter>

Next, the color filter according to the embodiment of the present invention will be described. The color filter according to the embodiment of the present invention has the film according to the embodiment of the present invention. More preferably, the color filter according to the embodiment of the present invention has the film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

The color filter according to the embodiment of the present invention may further have a pixel (hereinafter, also referred to as other pixels) different from the film (pixel) according to the embodiment of the present invention. Examples of the other pixels include red pixels, blue pixels, yellow pixels, cyan pixels, magenta pixels, transparent pixels, black pixels, and pixels of near-infrared transmission filter.

In the color filter according to the embodiment of the present invention, the thickness of the film according to the embodiment of the present invention can be appropriately adjusted depending on the purposes. The thickness of the film is preferably 20 μm or less, more preferably 10 μm or less, and still more preferably 5 μm or less. The lower limit of the thickness of the film is preferably 0.1 μm or more, more preferably 0.2 m or more, and still more preferably 0.3 μm or more.

In the color filter according to the embodiment of the present invention, the width of the pixel is preferably 0.5 to 20.0 μm. The lower limit is preferably 1.0 μm or more and more preferably 2.0 μm or more. The upper limit is preferably 15.0 m or less and more preferably 10.0 μm or less. In addition, the Young's modulus of the pixel is preferably 0.5 to 20 GPa and more preferably 2.5 to 15 GPa.

Each pixel included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50 to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹Ω×cm or more and more preferably 10¹¹Ω×cm or more. The upper limit is not specified, but is preferably, for example, 10¹⁴Ω×cm or less. The volume resistivity value of the pixel can be measured, for example, using an ultrahigh resistance meter 5410 (manufactured by Advantest Corporation).

In addition, in the color filter according to the embodiment of the present invention, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and still more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an inkjet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of a specific wavelength (for example, ultraviolet rays, near-infrared rays, and the like), a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. Examples of the ultraviolet absorber and near-infrared absorber include the above-described materials. The content of these additives can be appropriately adjusted, but is preferably 0.1 to 70 mass % and still more preferably 1 to 60 mass % with respect to the total weight of the protective layer.

In addition, as the protective layer, the protective layers described in paragraphs “0073” to “0092” of JP2017-151176A can also be used.

<Method for Manufacturing Color Filter>

Next, the method for manufacturing a color filter according to the embodiment of the present invention will be described. The color filter according to the embodiment of the present invention can be manufactured through a step of forming a coloring composition layer on a support using the above-described coloring composition according to the embodiment of the present invention, and a step of forming a pattern on the coloring composition layer by a photolithography method or a dry etching method.

(Photolithography Method)

First, a case of forming pattern by a photolithography method to manufacture a color filter will be described. Pattern formation by a photolithography method preferably includes a step of forming a coloring composition layer on a support using the coloring composition according to the embodiment of the present invention, a step of patternwise exposing the coloring composition layer, and a step of removing an unexposed area of the coloring composition layer by development to form a pattern (pixel). Optionally, a step (pre-baking step) of baking the coloring composition layer and a step (post-baking step) of baking the developed pattern (pixel) may be provided.

In the step of forming a coloring composition according to the embodiment of the present invention, the coloring composition layer is formed on a support using the coloring composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of substances, or planarize the surface of the substrate.

As a method of applying the coloring composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent—” (February, 2005, S.B. Research Co., Ltd.) and methods described in JP2003-262716A, JP2003-185831A, JP2003-261827A, JP2012-126830A, and JP2006-169325A. In addition, with regard to the method of applying the coloring composition, reference can be made to the description in WO2017/030174A and WO2017/018419A, the contents of which are incorporated herein by reference.

The coloring composition layer formed on the support may be dried (pre-baked). Ina case of producing a film by a low-temperature process, pre-baking may not be performed. In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. The pre-baking time is preferably 10 to 300 seconds, more preferably 40 to 250 seconds, and still more preferably 80 to 220 seconds. Pre-baking can be performed using a hot plate, an oven, or the like.

<<Exposure Step>>

Next, the coloring composition layer is patternwise exposed (exposing step). For example, the coloring composition layer can be patternwise exposed using a stepper exposure device or a scanner exposure device through a mask having a predetermined mask pattern. As a result, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the unexposed area of the coloring composition layer is removed by development to form a pattern (pixel). The unexposed area of the coloring composition layer can be removed by development using a developer. Thus, the coloring composition layer of the unexposed area in the exposure step is eluted into the developer, and as a result, only a photocured portion remains. As the developer, an organic alkaline developer causing no damage on a base of element, circuit, or the like is desirable. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

As the developer, an alkaline aqueous solution (alkaline developer) obtained by diluting an alkaline agent with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to perform an additional exposure treatment or a heat treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be performed by the method described in KR10-2017-122130A.

(Dry Etching Method)

Next, a case of forming pattern by a dry etching method to manufacture a color filter will be described. Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of patternwise exposing the photoresist layer and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heat treatment after exposure and a heat treatment after development (post-baking treatment) are performed. The details of the pattern formation by the dry etching method can be found in paragraphs “0010” to “0067” of JP2013-064993A, the content of which is incorporated herein by reference.

<Solid-State Imaging Element>

The solid-state imaging element according to the embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device-protective film formed of silicon nitride or the like, which is formed to cover the entire surface of the light-shielding film and the light receiving portion of the photodiodes, on the light-shielding film; and have a color filter on the device-protective film. Furthermore, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each coloring pixel is embedded in a space partitioned in, for example, a lattice shape by a partition wall. The partition wall in this case preferably has a low refractive index for each coloring pixel. Examples of an imaging device having such a structure include the devices described in JP2012-227478A, JP2014-179577A, and WO2018/043654A. An imaging device including the solid-state imaging element according to the embodiment of the present invention can also be used as a vehicle camera or a monitoring camera, in addition to a digital camera or electronic equipment (mobile phones or the like) having an imaging function.

<Image Display Device>

The image display device according to the embodiment of the present invention has the film according to the embodiment of the present invention. Examples of the image display device include a liquid crystal display device or an organic electroluminescence display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989)”, and the like. In addition, the details of a liquid crystal display device can be found in, for example, “Next-Generation Liquid Crystal Display Techniques (Edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Preparation of Dispersion Liquid>

A pigment (G pigment (green pigment): 8.29 parts by mass, Y pigment (yellow pigment): 2.07 parts by mass) shown in the following table, 1.03 parts by mass of a derivative shown in the following table, 15.12 parts by mass of a dispersant shown in the following table, and 71.92 parts by mass of propylene glycol monomethyl ether acetate (PGMEA) shown in the following tables were mixed. Thereafter, 230 parts by mass of zirconia beads having a diameter of 0.3 mm were added thereto to perform a dispersion treatment for 5 hours using a paint shaker, and the beads were separated by filtration to produce a dispersion liquid.

TABLE 1

| | G pigment | Y pigment | Derivative | Dispersant |
|---|---|---|---|---|
| Dispersion | SQ-1 | PY-185 | Derivative-1 | P-1 |
| liquid-1 | | | | |
| Dispersion | SQ-2 | PY-185 | Derivative-1 | P-1 |
| liquid-2 | | | | |
| Dispersion | SQ-3 | PY-185 | Derivative-1 | P-1 |
| liquid-3 | | | | |
| Dispersion | SQ-4 | PY-185 | Derivative-1 | P-1 |
| liquid-4 | | | | |
| Dispersion | SQ-7 | PY-185 | Derivative-1 | P-1 |
| liquid-5 | | | | |
| Dispersion | SQ-12 | PY-185 | Derivative-1 | P-1 |
| liquid-6 | | | | |
| Dispersion | SQ-13 | PY-185 | Derivative-1 | P-1 |
| liquid-7 | | | | |
| Dispersion | SQ-14 | PY-185 | Derivative-1 | P-1 |
| liquid-8 | | | | |
| Dispersion | SQ-15 | PY-185 | Derivative-1 | P-1 |
| liquid-9 | | | | |
| Dispersion | SQ-16 | PY-185 | Derivative-1 | P-1 |
| liquid-10 | | | | |
| Dispersion | SQ-17 | PY-185 | Derivative-1 | P-1 |
| liquid-11 | | | | |
| Dispersion | SQ-18 | PY-185 | Derivative-1 | P-1 |
| liquid-12 | | | | |
| Dispersion | SQ-19 | PY-185 | Derivative-1 | P-1 |
| liquid-13 | | | | |
| Dispersion | SQ-25 | PY-185 | Derivative-1 | P-1 |
| liquid-14 | | | | |
| Dispersion | SQ-29 | PY-185 | Derivative-1 | P-1 |
| liquid-15 | | | | |
| Dispersion | SQ-30 | PY-185 | Derivative-1 | P-1 |
| liquid-16 | | | | |
| Dispersion | SQ-32 | PY-185 | Derivative-1 | P-1 |
| liquid-17 | | | | |
| Dispersion | SQ-33 | PY-185 | Derivative-1 | P-1 |
| liquid-18 | | | | |
| Dispersion | SQ-34 | PY-185 | Derivative-1 | P-1 |
| liquid-19 | | | | |
| Dispersion | SQ-38 | PY-185 | Derivative-1 | P-1 |
| liquid-20 | | | | |
| Dispersion | SQ-39 | PY-185 | Derivative-1 | P-1 |
| liquid-21 | | | | |
| Dispersion | SQ-40 | PY-185 | Derivative-1 | P-1 |
| liquid-22 | | | | |
| Dispersion | SQ-45 | PY-185 | Derivative-1 | P-1 |
| liquid-23 | | | | |
| Dispersion | SQ-47 | PY-185 | Derivative-1 | P-1 |
| liquid-24 | | | | |
| Dispersion | SQ-51 | PY-185 | Derivative-1 | P-1 |
| liquid-25 | | | | |
| Dispersion | SQ-67 | PY-185 | Derivative-1 | P-1 |
| liquid-26 | | | | |
| Dispersion | SQ-74 | PY-185 | Derivative-1 | P-1 |
| liquid-27 | | | | |
| Dispersion | SQ-77 | PY-185 | Derivative-1 | P-1 |
| liquid-28 | | | | |
| Dispersion | SQ-96 | PY-185 | Derivative-1 | P-1 |
| liquid-29 | | | | |
| Dispersion | SQ-101 | PY-185 | Derivative-1 | P-1 |
| liquid-30 | | | | |
| Dispersion | SQ-104 | PY-185 | Derivative-1 | P-1 |
| liquid-31 | | | | |
| Dispersion | SQ-108 | PY-185 | Derivative-1 | P-1 |
| liquid-32 | | | | |
| Dispersion | SQ-110 | PY-185 | Derivative-1 | P-1 |
| liquid-33 | | | | |
| Dispersion | SQ-124 | PY-185 | Derivative-1 | P-1 |
| liquid-34 | | | | |
| Dispersion | SQ-1 | PY-139 | Derivative-1 | P-1 |
| liquid-35 | | | | |
| Dispersion | SQ-1 | PY-150 | Derivative-1 | P-1 |
| liquid-36 | | | | |
| Dispersion | SQ-1 | PY-185 | Derivative-1 | P-1 |
| liquid-37 | | | | |
| Dispersion | SQ-1 | PY-185 | Derivative-1 | P-4 |
| liquid-38 | | | | |
| Dispersion | SQ-1 | PY-185 | Derivative-1 | P-1 |
| liquid-39 | | | | |
| Dispersion | SQ-1 | PY-185 | Derivative-1 | P-1 |
| liquid-40 | | | | |
| Dispersion | SQ-1 | PY-185 | Derivative-1 | P-2 |
| liquid-41 | | | | |
| Dispersion | SQ-1 | PY-185 | Derivative-1 | P-3 |
| liquid-42 | | | | |
| Dispersion | SQ-R1 | PY-185 | Derivative-1 | P-1 |
| liquid-43 | | | | |
| Dispersion | PG-58 | PY-185 | Derivative-1 | P-1 |
| liquid-44 | | | | |
| Dispersion | PG-36 | PY-185 | Derivative-1 | P-1 |
| liquid-45 | | | | |

Details of the materials indicated by the abbreviations in the above tables are as follows.

[G Pigment]

PG-36: C.I. Pigment Green 36 (phthalocyanine compound)

PG-58: C.I. Pigment Green 58 (phthalocyanine compound)

SQ-1, SQ-2, SQ-3, SQ-4, SQ-7, SQ-12, SQ-13, SQ-14, SQ-15, SQ-16, SQ-17, SQ-18, SQ-19, SQ-25, SQ-29, SQ-30, SQ-32, SQ-33, SQ-34, SQ-38, SQ-39, SQ-40, SQ-45, SQ-47, SQ-51, SQ-67, SQ-74, SQ-77, SQ-96, SQ-101, SQ-104, SQ-108, SQ-110, SQ-124: compounds having the structures described in the specific examples of the squarylium compound A described above

SQ-R¹: compound having the following structure (squarylium compound)

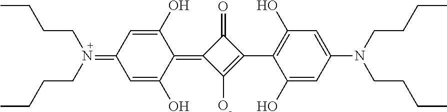

The solubility, maximum absorption wavelength, and average value (average SP value) of solubility parameters (SP values) of the groups in the sites corresponding to R^{a11}, R^{a12}, R^{a21}, and R^{a22} of Formula (1), which relate to the squarylium compound used as the G pigment in PGMEA at 25° C., are as follows.

The SP value was calculated in accordance with the Okitsu method (“Journal of the Adhesion Society of Japan”, 29(5) (1993), authored by Toshinao Okitsu). Specifically, the SP value was calculated using the following expression. ΔF denotes the value described in the journal. In addition, the SP value of each group was calculated by replacing the bonding hand (position at which the nitrogen atom of Formula (1) is bonded) with a hydrogen atom.

SP value (δ)=ΣΔF (Molar Attraction Constants)/V (molar volume)

In addition, the maximum absorption wavelength was obtained by dissolving 50 mg of each compound in 200 mL of chloroform, adding chloroform to 2 mL of this solution so as to be 200 mL, and measuring the absorbance of the solution in a wavelength range of 400 to 800 nm using Cary 5000 UV-Vis-NIR spectrophotometer (manufactured by Agilent Technologies, Inc.).

In addition, the solubility was measured by adding 4.0 mg, 5.0 mg, or 6.0 mg of each compound in 200 mL of PGMEA at 25° C., stirring the solution for 15 minutes at room temperature, allowing the solution to stand for 15 minutes, and visually checking the presence or absence of insoluble matters. The evaluation standard is as follows.

A: solubility is 20 mg/L or less.

B: solubility is more than 20 mg/L and 25 mg or less.

C: solubility is more than 25 mg/L and 30 mg or less.

D: solubility is more than 30 mg/L.

TABLE 2

| | | Maximum | |
|---|---|---|---|
| | Average | absorption | |
| | SP value | wavelength | |
| Type | (cal/cm³)^{1/2} | nm | Solubility |
| SQ-1 | 10.33 | 670 | A |
| SQ-2 | 9.76 | 675 | B |
| SQ-3 | 9.76 | 675 | B |
| SQ-4 | 9.76 | 675 | B |
| SQ-7 | 9.49 | 680 | C |
| SQ-12 | 11.10 | 665 | A |
| SQ-13 | 9.69 | 675 | B |
| SQ-14 | 9.40 | 670 | C |
| SQ-15 | 9.99 | 680 | B |
| SQ-16 | 11.31 | 660 | A |
| SQ-17 | 10.16 | 675 | A |
| SQ-18 | 10.00 | 685 | A |
| SQ-19 | 10.98 | 670 | A |
| SQ-25 | 9.93 | 665 | B |
| SQ-29 | 10.50 | 680 | A |
| SQ-30 | 10.06 | 665 | A |
| SQ-32 | 9.88 | 660 | B |
| SQ-33 | 10.31 | 675 | A |
| SQ-34 | 9.91 | 665 | B |
| SQ-38 | 9.87 | 675 | B |
| SQ-39 | 10.24 | 670 | A |
| SQ-40 | 10.24 | 675 | A |
| SQ-45 | 10.15 | 675 | A |
| SQ-47 | 9.32 | 670 | C |
| SQ-51 | 9.22 | 685 | C |
| SQ-67 | 9.42 | 675 | C |
| SQ-74 | 11.10 | 665 | A |
| SQ-77 | 10.33 | 670 | A |
| SQ-96 | 10.33 | 690 | A |
| SQ-101 | 10.33 | 690 | A |
| SQ-104 | 10.33 | 695 | A |
| SQ-108 | 11.39 | 685 | A |
| SQ-110 | 10.15 | 675 | A |
| SQ-124 | 8.94 | 680 | C |
| SQ-R1 | 6.98 | 655 | D |

[Y Pigment]

PY-139: C. I. Pigment Yellow 139

PY-150: C. I. Pigment Yellow 150

PY-185: C. I. Pigment Yellow 185

[Derivative]

Derivatives 1 to 5: compounds having the following structures

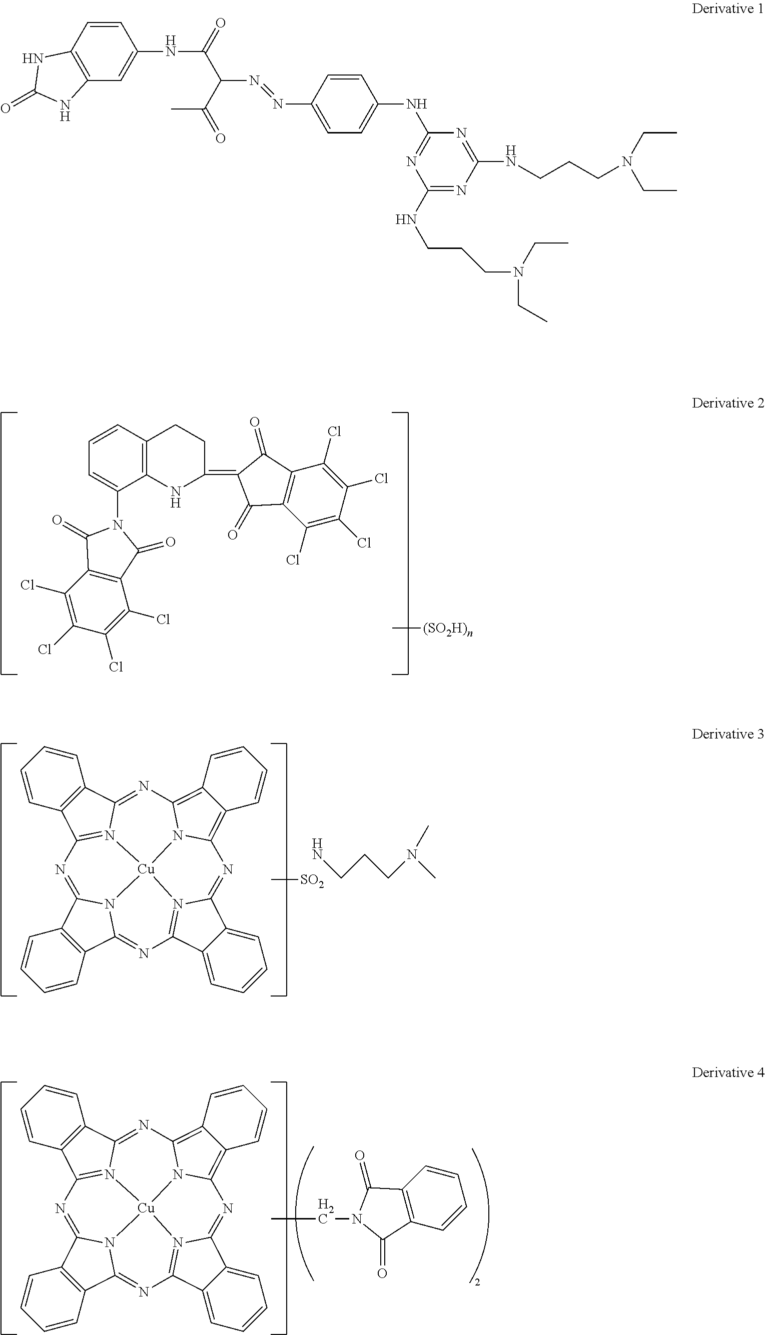

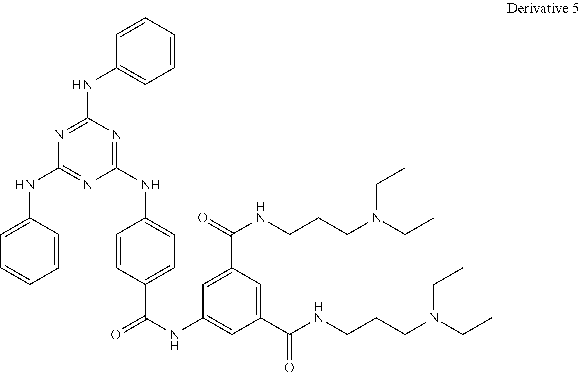 [SMILES: CCN(CC)CCCNC(=O)c1cc(NC(=O)c2ccc(Nc3nc(Nc4ccccc4)nc(Nc4ccccc4)n3)cc2)cc(C(=O)NCCCN(CC)CC)c1]

[Dispersant]

P-1: 30 mass % of propylene glycol monomethyl ether acetate (PGMEA) solution of a resin having the following structure (the numerical value described together with the main chain indicates a molar ratio, and the numerical value described together with the side chain indicates the number of repeating units, Mw=20,000)

P-2: 30 mass % of PGMEA solution of a resin having the following structure (the numerical value described together with the main chain indicates a molar ratio, and the numerical value described together with the side chain indicates the number of repeating units, Mw=18,000)

P-3: 30 mass % of PGMEA solution of a resin having the following structure (the numerical value described together with the main chain indicates a molar ratio, and the numerical value described together with the side chain indicates the number of repeating units, Mw=22,000)

P-4: 20 mass % of PGMEA solution of a resin having the following structure (the numerical value described together with the main chain indicates a molar ratio, and the numerical value described together with the side chain indicates the number of repeating units, Mw=22,900)

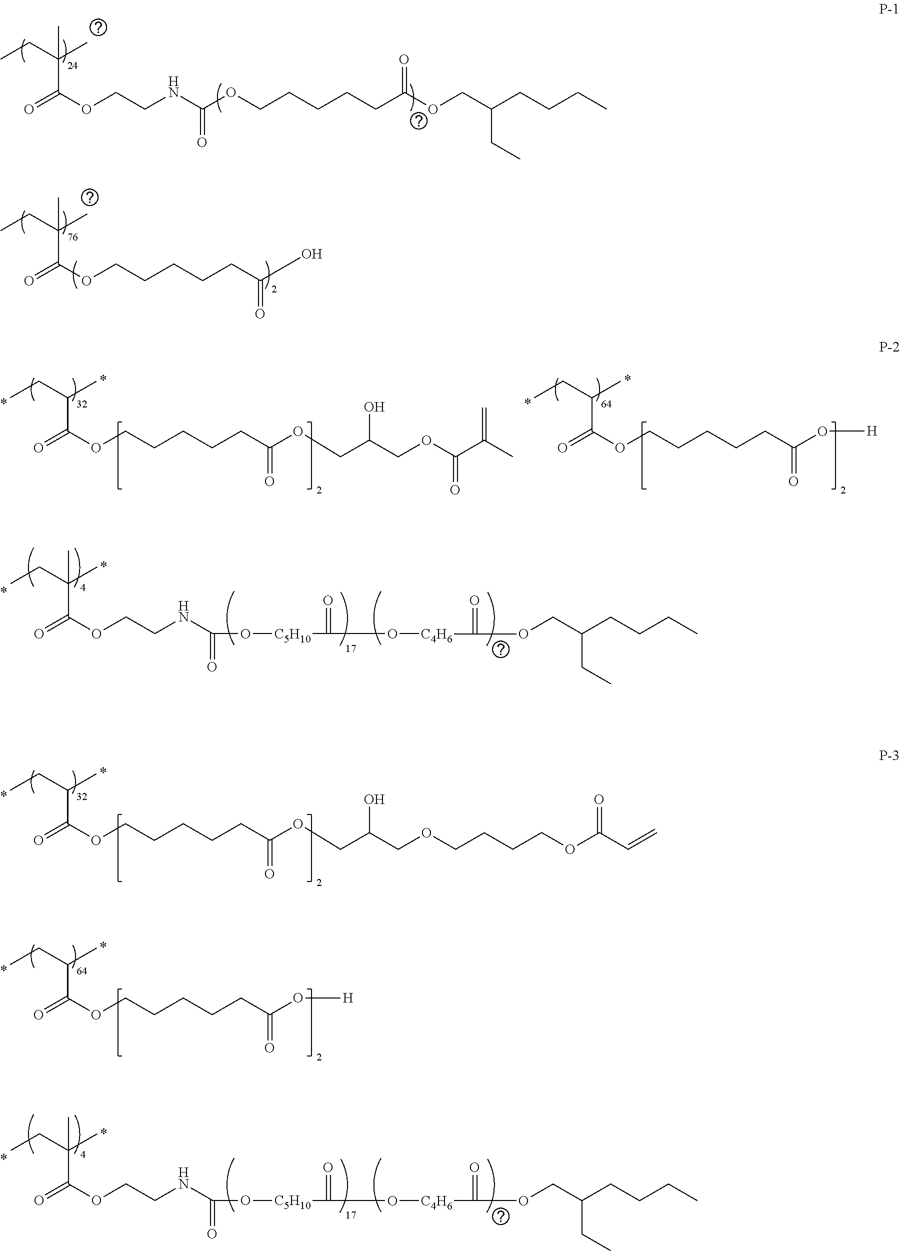

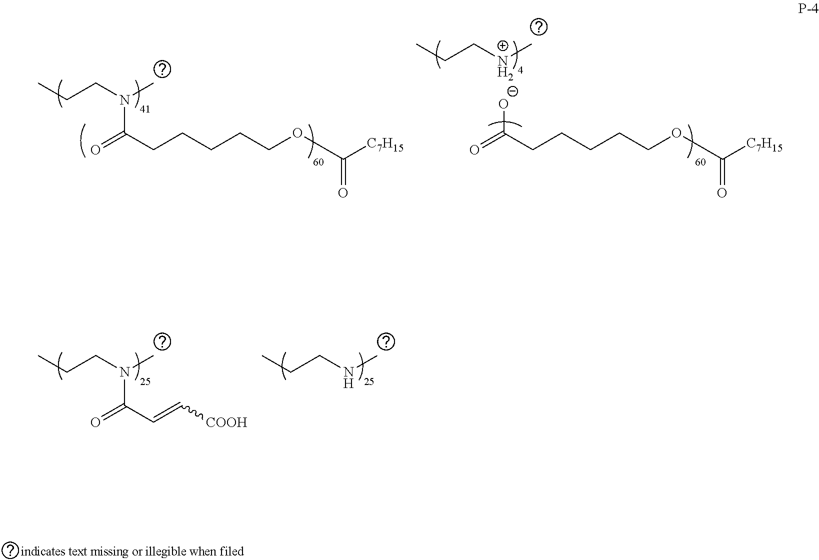

### Examples 1 to 42 and Comparative Examples 1 to 3

The following raw materials were mixed to prepare a coloring composition.

Dispersion liquid of the types shown in the following tables . . . 39.4 parts by mass

Resin D1 . . . 0.58 parts by mass

Polymerizable compound E1 (KAYARAD DPHA, manufactured by Nippon Kayaku Co., Ltd.) . . . 0.54 parts by mass

Photopolymerization initiator F3 . . . 0.33 parts by mass

Surfactant H1 . . . 4.17 parts by mass

p-methoxyphenol . . . 0.0006 parts by mass

PGMEA . . . 7.66 parts by mass

Details of the materials indicated by the above abbreviations are as follows.

Resin D1: resin having the following structure (the numerical value described together with the main chain indicates a molar ratio, Mw=11,000)

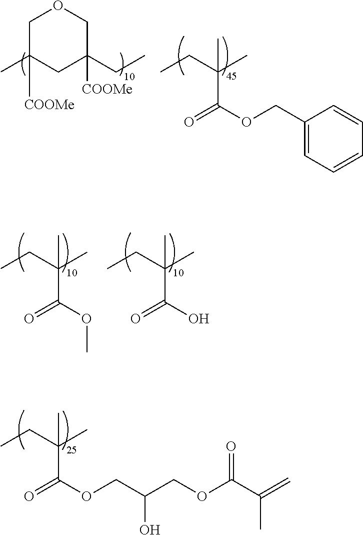

Polymerizable compound E1: KAYARAD DPHA (manufactured by Nippon Kayaku Co., Ltd.)

Photopolymerization initiator F3: compound having the following structure

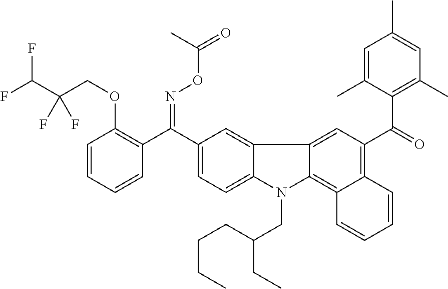 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

Surfactant H1: 1 mass % PGMEA solution of the following mixture (Mw=14000; in the following formula, “%” representing the proportion of a repeating unit is mol %)

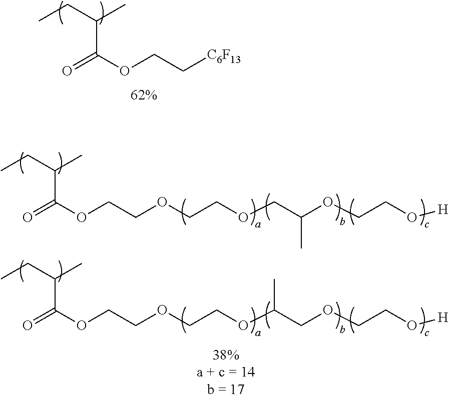

<Evaluation of Storage Stability>

The viscosity of the coloring composition obtained as described above was measured by “RE-85L” manufactured by TOKI SANGYO CO., LTD. After that, the coloring composition was left to stand under the conditions of 45° C. and 3 days, and then the viscosity thereof was measured again. Storage stability was evaluated according to the following evaluation standard from a viscosity difference (ΔVis) before and after leaving to stand. It can be said that the smaller the numerical value of the viscosity difference (ΔVis), the better the storage stability. The viscosity of the coloring composition was measured in a state in which the temperature was adjusted to 25° C. The evaluation standard is as follows, and the evaluation results are shown in the tables below.

[Evaluation Standard]

A: ΔVis was 0.5 mPa×s or less.

B: ΔVis was more than 0.5 mPa×s and 2.0 mPa×s or less.

C: ΔVis was more than 2.0 mPa×s.

<Evaluation of Spectral Characteristics>

Each coloring composition was applied to a glass substrate by spin coating so that the thickness of a film after post-baking was 0.6 μm. The coloring composition was dried by a hot plate at 100° C. for 120 seconds. Next, a heat treatment (post-baking) was performed for 300 seconds using a hot plate at 200° C. to form a film. Using an ultraviolet-visible near infrared spectrophotometer U-4100 (manufactured by Hitachi High-Tech Corporation) (ref glass substrate), the light transmittance of the glass substrate on which the film formed was measured in a wavelength range of 300 to 1000 nm. The spectral evaluation was performed by comparing the values of transmittance ratio of 570 nm and 650 nm (T=(transmittance at 570 nm)/(transmittance at 650 nm)×100). In a case where the tail of the absorption spectrum is good, since the transmittance at 650 nm is low and the transmittance at 570 nm is high, as the transmittance ratio of 570 nm and 650 nm is larger, the spectrum is better. The evaluation standard is as follows, and the evaluation results are shown in the tables below.

[Evaluation Standard]

A: 14≤T

B: 12≤T<14

C: 10≤T<12

D: T<10

<Evaluation of Heat Resistance>

A 5 cm×5 cm glass substrate was coated with each coloring composition using a spin coater so that the thickness of a film after drying was 0.6 μm, and pre-baking was performed at 100° C. for 120 seconds to obtain a monochromatic color filter for evaluation of heat resistance. The glass substrate on which this color filter was formed was placed on a hot plate at 200° C. such that the substrate surface was in contact with the hot plate, and was heated for 1 hour. After that, using a colorimeter MCPD-1000 (manufactured by OTSUKA ELECTRONICS Co., Ltd.), the color difference (ΔE*ab value) of the color filter before and after heating was measured, and the heat resistance was evaluated according to the following judgement standard. As the ΔE*ab value is smaller, heat resistance is better. The ΔE*ab value is a value acquired using the following color difference expression based on the CIE1976 (L*, a*, b*) space color system (The Color Science Handbook (1985), new edition, p. 266, edited by The Color Science Association of Japan).

ΔE*ab={(ΔL*)²+(Δa*)²+(Δb*)²}^{1/2}

[Evaluation Standard]

A: ΔE*ab value is less than 1.0.

B: ΔE*ab value is 1.0 or more and less than 3.0.

C: ΔE*ab value is 3.0 or more.

<Evaluation of Light Resistance>

A 5 cm×5 cm glass substrate was coated with each coloring composition using a spin coater so that the thickness of a film after drying was 0.6 μm, and pre-baking was performed at 100° C. for 120 seconds to obtain a monochromatic color filter for evaluation of light resistance. A SiO₂ layer having a thickness of 100 nm was formed on this color filter by a chemical vapor deposition method. For the purpose of cutting off light of 380 nm or less, a sharp cut filter L38 manufactured by HOYA Corporation was placed on the obtained monochromatic color filter for evaluation of light resistance, and the obtained monochromatic color filter for evaluation of light resistance was irradiated with light of a xenon lamp at 100000 for 20 hours (equivalent to 2000000 lux×h). The color difference (ΔE*ab value) of the color filter before and after irradiation with xenon lamp was measured.

[Evaluation Standard]

A: ΔE*ab value is less than 5.0.

B: ΔE*ab value is 5.0 or more and less than 10.0.

C: ΔE*ab value is 10.0 or more.

TABLE 3

| | | Spectral | Storage | Heat | Light |
|---|---|---|---|---|---|
| | Dispersion liquid | characteristics | stability | resistance | resistance |
| Example 1 | Dispersion liquid-1 | A | A | A | A |
| Example 2 | Dispersion liquid-2 | B | B | A | B |
| Example 3 | Dispersion liquid-3 | B | B | A | B |
| Example 4 | Dispersion liquid-4 | A | B | A | B |
| Example 5 | Dispersion liquid-5 | B | B | B | B |
| Example 6 | Dispersion liquid-6 | A | A | A | A |
| Example 7 | Dispersion liquid-7 | B | B | A | B |
| Example 8 | Dispersion liquid-8 | B | B | B | B |
| Example 9 | Dispersion liquid-9 | B | B | A | B |
| Example 10 | Dispersion liquid-10 | B | A | A | A |
| Example 11 | Dispersion liquid-11 | B | A | B | A |
| Example 12 | Dispersion liquid-12 | B | A | B | A |
| Example 13 | Dispersion liquid-13 | B | A | A | A |
| Example 14 | Dispersion liquid-14 | A | B | A | B |
| Example 15 | Dispersion liquid-15 | B | A | A | A |
| Example 16 | Dispersion liquid-16 | A | A | B | A |
| Example 17 | Dispersion liquid-17 | A | B | A | B |
| Example 18 | Dispersion liquid-18 | B | A | B | A |
| Example 19 | Dispersion liquid-19 | A | B | A | B |
| Example 20 | Dispersion liquid-20 | A | B | A | B |
| Example 21 | Dispersion liquid-21 | B | A | B | A |
| Example 22 | Dispersion liquid-22 | C | A | B | A |
| Example 23 | Dispersion liquid-23 | B | A | B | A |
| Example 24 | Dispersion liquid-24 | B | B | B | B |
| Example 25 | Dispersion liquid-25 | D | B | C | B |
| Example 26 | Dispersion liquid-26 | D | B | B | B |
| Example 27 | Dispersion liquid-27 | B | A | A | A |
| Example 28 | Dispersion liquid-28 | B | A | A | A |
| Example 29 | Dispersion liquid-29 | D | A | B | A |
| Example 30 | Dispersion liquid-30 | C | A | B | A |
| Example 31 | Dispersion liquid-31 | C | A | B | A |
| Example 32 | Dispersion liquid-32 | B | A | A | A |
| Example 33 | Dispersion liquid-33 | B | A | B | A |
| Example 34 | Dispersion liquid-34 | B | B | C | B |
| Example 35 | Dispersion liquid-35 | A | A | A | A |
| Example 36 | Dispersion liquid-36 | A | A | A | A |
| Example 37 | Dispersion liquid-37 | A | A | A | A |
| Example 38 | Dispersion liquid-38 | B | A | A | A |
| Example 39 | Dispersion liquid-39 | B | A | A | A |
| Example 40 | Dispersion liquid-40 | A | A | A | A |
| Example 41 | Dispersion liquid-41 | A | A | A | A |
| Example 42 | Dispersion liquid-42 | A | A | A | A |
| Comparative Example 1 | Dispersion liquid-44 | C | C | A | C |
| Comparative Example 2 | Dispersion liquid-45 | D | C | A | C |
| Comparative Example 3 | Dispersion liquid-43 | — | — | — | — |

As shown in the above table, the coloring compositions of Examples had good storage stability, and were capable of produce a film having excellent light resistance. The coloring composition of Comparative Example 3 using Dispersion liquid-43 was gelled, and thus each item was not evaluated.

In addition, even in a case 1 part by mass of tetrabutylammonium bis(3,4,6-trichloro-1,2-benzenedithiolato)nickelate was further added to the coloring composition of Example 1 as a near-infrared absorber, the same results as in Example 1 were obtained.

### Examples 43 to 63

The following raw materials were mixed to prepare a coloring composition.

Dispersion liquid . . . parts by mass described in the following table

Resin . . . parts by mass described in the following table

Polymerizable compound . . . parts by mass described in the following table

Photopolymerization initiator . . . parts by mass described in the following table

Surfactant H1 . . . 4.17 parts by mass

p-methoxyphenol . . . 0.0006 parts by mass

Organic solvent . . . parts by mass described in the following table

TABLE 4

| | | | | | | Polymerizable | | Photopolymerization | | | |
|---|---|---|---|---|---|---|---|---|---|---|---|
| | | Dispersion liquid | | Resin | | compound | | initiator | | Organic solvent | |
| | | | Part by | | Part by | | Part by | | Part by | | Part by |
| | | Type | mass | Type | mass | Type | mass | Type | mass | Type | mass |
| Example | 43 | Dispersion liquid-1 | 19.7 | D1 | 0.58 | E1 | 0.54 | F3 | 0.33 | PGMEA | 7.66 |
| | | Dispersion liquid-6 | 19.7 | | | | | | | | |
| | 44 | Dispersion liquid-1 | 19.7 | D1 | 0.58 | E1 | 0.54 | F3 | 0.33 | PGMEA | 7.66 |
| | | Dispersion liquid-27 | 19.7 | | | | | | | | |
| | 45 | Dispersion liquid-20 | 19.7 | D1 | 0.58 | E1 | 0.54 | F3 | 0.33 | PGMEA | 7.66 |
| | | Dispersion liquid-33 | 19.7 | | | | | | | | |
| | 46 | Dispersion liquid-1 | 19.7 | D1 | 0.58 | E1 | 0.54 | F3 | 0.33 | PGMEA | 7.66 |
| | | Dispersion liquid-44 | 19.7 | | | | | | | | |
| | 47 | Dispersion liquid-1 | 19.7 | D1 | 0.58 | E1 | 0.54 | F3 | 0.33 | PGMEA | 7.66 |
| | | Dispersion liquid-45 | 19.7 | | | | | | | | |
| | 48 | Dispersion liquid-1 | 19.7 | D1 | 0.58 | E1 | 0.54 | F3 | 0.33 | PGMEA | 7.66 |
| | | Dispersion liquid-35 | 19.7 | | | | | | | | |
| | 49 | Dispersion liquid-1 | 19.7 | D1 | 0.58 | E1 | 0.54 | F3 | 0.33 | PGMEA | 7.66 |
| | | Dispersion liquid-36 | 19.7 | | | | | | | | |
| | 50 | Dispersion liquid-1 | 19.7 | D1 | 0.58 | E1 | 0.54 | F3 | 0.33 | PGMEA | 7.66 |
| | | Dispersion liquid-40 | 19.7 | | | | | | | | |
| | 51 | Dispersion liquid-1 | 39.4 | D2 | 0.58 | E1 | 0.54 | F3 | 0.33 | PGMEA | 7.66 |
| | 52 | Dispersion liquid-1 | 39.4 | D1 | 0.29 | E1 | 0.54 | F3 | 0.33 | PGMEA | 7.66 |
| | | | | D2 | 0.29 | | | | | | |
| | 53 | Dispersion liquid-1 | 39.4 | D1 | 0.58 | E2 | 0.54 | F3 | 0.33 | PGMEA | 7.66 |
| | 54 | Dispersion liquid-1 | 39.4 | D1 | 0.58 | E3 | 0.54 | F3 | 0.33 | PGMEA | 7.66 |
| | 55 | Dispersion liquid-1 | 39.4 | D1 | 0.58 | E4 | 0.54 | F3 | 0.33 | PGMEA | 7.66 |
| | 56 | Dispersion liquid-1 | 39.4 | D1 | 0.58 | E5 | 0.54 | F3 | 0.33 | PGMEA | 7.66 |
| | 57 | Dispersion liquid-1 | 39.4 | D1 | 0.58 | E1 | 0.27 | F3 | 0.33 | PGMEA | 7.66 |
| | | | | | | E2 | 0.27 | | | | |
| | 58 | Dispersion liquid-1 | 39.4 | D1 | 0.58 | E1 | 0.54 | F1 | 0.33 | PGMEA | 7.66 |
| | 59 | Dispersion liquid-1 | 39.4 | D1 | 0.58 | E1 | 0.54 | F2 | 0.33 | PGMEA | 7.66 |
| | 60 | Dispersion liquid-1 | 39.4 | D1 | 0.58 | E1 | 0.54 | F5 | 0.33 | PGMEA | 7.66 |
| | 61 | Dispersion liquid-1 | 39.4 | D1 | 0.58 | E1 | 0.54 | F1 | 0.1 | PGMEA | 7.66 |
| | | | | | | | | F3 | 0.23 | | |
| | 62 | Dispersion liquid-1 | 39.4 | D1 | 0.58 | E1 | 0.54 | F3 | 0.23 | PGMEA | 7.66 |
| | | | | | | | | F4 | 0.1 | | |
| | 63 | Dispersion liquid-1 | 39.4 | D1 | 0.58 | E1 | 0.54 | F3 | 0.33 | PGMEA | 3.83 |
| | | | | | | | | | | Cyclohexane | 3.83 |

Among the materials described by the abbreviations in the above table, details other than the above-described materials are as follows.

[Resin]

D2: resin having the following structure (the numerical value described together with the main chain indicates a molar ratio, Mw=14000)

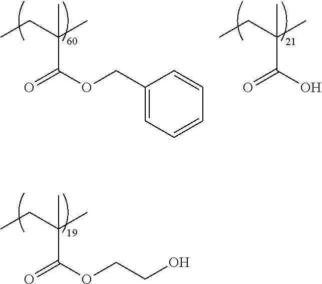

[Polymerizable Compound]

E2: ARONIX M-305 (manufactured by TOAGOSEI CO., LTD.)

E3: NK ESTER A-TMMT (manufactured by Shin-Nakamura Chemical Co., Ltd.)

E4: KAYARAD RP-1040 (manufactured by Nippon Kayaku Co., Ltd.)

E5: ARONIX TO-2349 (manufactured by TOAGOSEI CO., LTD.)

[Photopolymerization Initiator]

F1: compound having the following structure (oxime-based photopolymerization initiator)

F2: compound having the following structure (oxime-based photopolymerization initiator)

F4: compound having the following structure (alkylphenone-based photopolymerizationinitiator)

F5: compound having the following structure (oxime-based photopolymerization initiator)

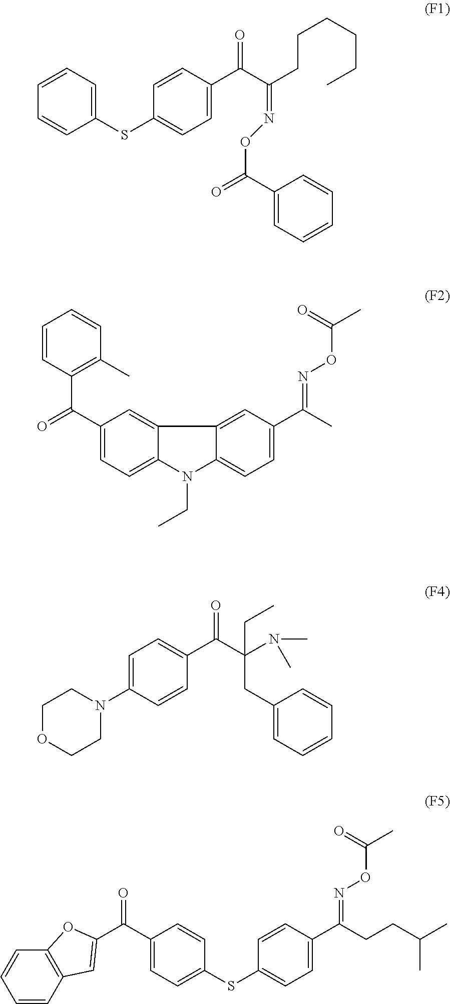 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCC(Cc1ccccc1)(C(=O)c1ccc(N2CCOCC2)cc1)N(C)C ; CC(=O)O/N=C(\CCC(C)C)c1ccc(Sc2ccc(C(=O)c3cc4ccccc4o3)cc2)cc1]

Regarding the obtained coloring compositions, the spectral characteristics, storage stability, heat resistance, and light resistance were evaluated in the same manner as in Example 1.

TABLE 5

| | | Spectral | Storage | Heat | Light |
|---|---|---|---|---|---|
| | | characteristics | stability | resistance | resistance |
| Example | 43 | A | A | A | A |
| | 44 | A | A | A | A |
| | 45 | A | B | A | A |
| | 46 | B | A | A | B |
| | 47 | C | A | A | B |
| | 48 | A | A | A | A |
| | 49 | A | A | A | A |
| | 50 | A | A | A | A |
| | 51 | A | A | A | A |
| | 52 | A | A | A | A |
| | 53 | A | A | A | A |
| | 54 | A | A | A | A |
| | 55 | A | A | A | A |
| | 56 | A | A | A | A |
| | 57 | A | A | A | A |
| | 58 | A | A | A | A |
| | 59 | A | A | A | A |
| | 60 | A | A | A | A |
| | 61 | A | A | A | A |
| | 62 | A | A | A | A |
| | 63 | A | A | A | A |
| | | A | A | A | A |

As shown in the above table, the coloring compositions of Examples had good storage stability, and were capable of produce a film having excellent light resistance.

### Example 64

A silicon wafer was coated with a Green composition using a spin coating method so that the thickness of a film after film formation was 1.0 μm. Next, the coating film was heated using a hot plate at 100° C. for 2 minutes. Next, using an i-ray stepper exposure device FPA-3000 i5+(manufactured by Canon Corporation), exposure was performed with light having an exposure dose of 1,000 mJ/cm² through a mask having a dot pattern of 2 μm square. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the Green composition was patterned by heating at 200° C. for 5 minutes using a hot plate. Likewise, a Red composition and a Blue composition were sequentially patterned to form red, green, and blue-colored patterns (Bayer pattern).

As the Green composition, the coloring composition of Example 1 was used.

The Red composition and the Blue composition will be described later.

The Bayer pattern refers to a pattern, as disclosed in the specification of U.S. Pat. No. 3,971,065A, in which a 2×2 array of color filter element having one Red element, two Green elements, and one Blue element is repeated.

The obtained color filter was incorporated into a solid-state imaging element according to a known method. The solid-state imaging element had a suitable image recognition ability.

—Red Composition—

The following components were mixed and stirred, and the obtained mixture was filtered through a nylon filter (manufactured by Nihon Pall Corporation) having a pore size of 0.45 μm to prepare a Red composition.

Red pigment dispersion liquid: 51.7 parts by mass

40 mass % PGMEA solution of resin D1: 0.6 parts by mass

Polymerizable compound E6: 0.6 parts by mass

Photopolymerization initiator F1: 0.3 parts by mass

Surfactant H1: 4.2 parts by mass

PGMEA: 42.6 parts by mass

—Blue Composition—

The following components were mixed and stirred, and the obtained mixture was filtered through a nylon filter (manufactured by Nihon Pall Corporation) having a pore size of 0.45 μm to prepare a Blue composition.

Blue pigment dispersion liquid: 44.9 parts by mass

40 mass % PGMEA solution of resin D1: 2.1 parts by mass

Polymerizable compound E1: 1.5 parts by mass

Polymerizable compound E6: 0.7 parts by mass

Photopolymerization initiator F1: 0.8 parts by mass

Surfactant H1: 4.2 parts by mass

PGMEA: 45.8 parts by mass

The raw materials used for the Red composition and the Blue composition are as follows.

Red Pigment Dispersion Liquid

A mixed solution consisting of 9.6 parts by mass of C.I. Pigment Red 254, 4.3 parts by mass of C.I. Pigment Yellow 139, 6.8 parts by mass of a dispersant (Disperbyk-161, manufactured by BYK Chemie), and 79.3 parts by mass of PGMEA was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Red pigment dispersion liquid was obtained.

Blue Pigment Dispersion Liquid

9.7 parts by mass of C.I. Pigment Blue 15:6, 2.4 parts by mass of C.I. Pigment Violet 23, 5.5 parts by mass of a dispersant (Disperbyk-161, manufactured by BYK Chemie), 82.4 parts by mass of PGMEA were mixed with each other to obtain a mixed solution, and the mixed solution was mixed and dispersed using a beads mill (zirconia beads; diameter: 0.3 mm) for 3 hours. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Blue pigment dispersion liquid was obtained.

Resin D1, polymerizable compound E1, photopolymerization initiator F1, and surfactant H1: above-described materials

Polymerizable compound E6: compound having the following structure

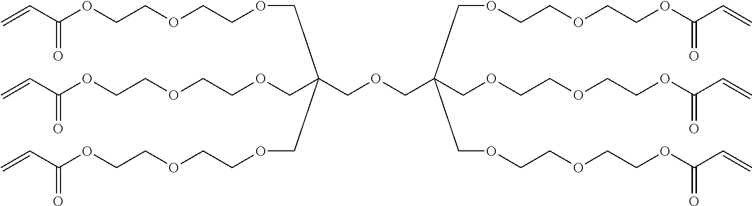 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

What is claimed is:

1. A coloring composition comprising:
a green colorant;
a resin; and
an organic solvent,
wherein the green colorant includes a squarylium compound having a solubility of 30 mg/L or less in propylene glycol methyl ether acetate at 25° C.

2. The coloring composition according to claim 1,
wherein the squarylium compound is a compound having a maximum absorption wavelength in a wavelength range of 600 to 700 nm.

3. The coloring composition according to claim 1,
wherein the squarylium compound is a compound represented by Formula (1), 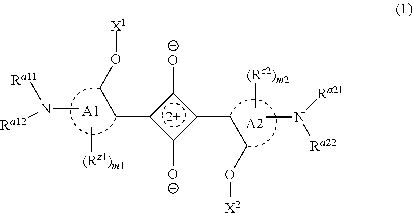
in Formula (1), A1 and A2 each independently represent an aromatic ring structure which may have a fused ring,
R^{z1} and R^{z2} each independently represent a substituent,
at least one of R^{z1}'s and at least one of R^{z2}'s may be bonded to each other to form a ring structure,
m1 represents an integer of 0 to mA1, in which mA1 represents a maximum number of substituents in A1,
m2 represents an integer of 0 to mA2, in which mA2 represents a maximum number of substituents in A2,
R^{z1} may form a ring structure with any one of R^{a11} or R^{a12},
R^{z2} may form a ring structure with anyone of R^{a21} or R^{a22},
X¹ and X² each independently represent a hydrogen atom or a substituent, in which X and X² may be bonded to each other to form a ring structure,
R^{a11}, R^{a12}, R^{a21}, and R^{a22} each independently represent an aromatic ring structure which may have a fused ring, and
at least one of R^{a11}, R^{a12}, R^{a21}, or R^{a22} represents an aromatic ring structure having a substituent at an adjacent position to an atom to which a nitrogen atom provided by A1 or A2 in Formula (1) is bonded, or an aromatic ring structure having a fused ring at the adjacent position to the atom to which the nitrogen atom of Formula (1) is bonded.

4. The coloring composition according to claim 3,
wherein an average value of solubility parameters of R^{a11}, R^{a12}, R^{a21}, and R^{a22} in Formula (1) is 8.9 (cal/cm³)^{1/2} or more.

5. The coloring composition according to claim 1, further comprising:
a yellow pigment.

6. The coloring composition according to claim 1, further comprising:
a pigment derivative.

7. The coloring composition according to claim 1, further comprising:
a polymerizable compound.

8. The coloring composition according to claim 1, further comprising:
a photopolymerization initiator.

9. The coloring composition according to claim 1,
wherein the resin includes an alkali-soluble resin.

10. The coloring composition according to claim 1,
wherein the coloring composition is used for forming a pixel of a color filter.

11. A film which is formed of the coloring composition according to claim 1.

12. A color filter comprising:
the film according to claim 11.

13. A method for manufacturing a color filter, comprising:
forming a coloring composition layer on a support using the coloring composition according to claim 1; and
forming a pattern on the coloring composition layer by a photolithography method or a dry etching method.

14. A solid-state imaging element comprising:
the film according to claim 11.

15. An image display device comprising:
the film according to claim 11.
